(19) United States
(12) Patent Application Publication
(10) Pub. No.: US 2026/0150672 A1
(43) Pub. Date: May 28, 2026

(54) METHOD FOR MANUFACTURING SEMICONDUCTOR DEVICE, SEMICONDUCTOR DEVICE, AND VEHICLE

(71) Applicant: ROHM CO., LTD., Kyoto-shi (JP)

(72) Inventors: Tomohiro YASUNISHI, Kyoto-shi (JP); Hideki SAWADA, Kyoto-shi (JP)

(21) Appl. No.: 19/453,588

(22) Filed: Jan. 20, 2026

Related U.S. Application Data
(63) Continuation of application No. PCT/JP2024/024181, filed on Jul. 4, 2024.

(30) Foreign Application Priority Data
Jul. 26, 2023 (JP) 2023-121246

(51) Int. Cl. H10W 40/20; H10W 40/00; H10W 40/22; H10W 74/10; H10W 74/47; H10W 90/00; H10W 90/10

(52) U.S. Cl. CPC H10W 40/235; H10W 40/037; H10W 40/22; H10W 74/114; H10W 74/47; H10W 90/10; H10W 90/753

(57) ABSTRACT

A method for manufacturing a semiconductor device including a base material bonded to the heat dissipating member is configured to more reliably retain the shape of a sealing resin. The method includes a first process, a second process, and a third process. The first process includes bonding a base material to a heat dissipating member, where the base material includes an insulating layer and a conductive layer positioned on a first side in a first direction relative to the insulating layer. The second process includes bonding a semiconductor element to the conductive layer. The third process includes forming the sealing resin that covers the semiconductor element. In the first process, the base material is bonded to the heat dissipating member with the insulating layer positioned between the heat dissipating member and the conductive layer. The third process is performed after completion of each of the first process and the second process.

### TECHNICAL FIELD

The present disclosure relates to a method for manufacturing a semiconductor device, a semiconductor device manufactured by the method, and a vehicle equipped with the semiconductor device.

### BACKGROUND ART

Conventionally, semiconductor devices incorporating semiconductor elements with switching functions (such as MOSFETs and IGBTs) are widely known and are typically used in power conversion applications. WO2019/239997A1 discloses an example of such a semiconductor device. The semiconductor device disclosed in the document includes a base material (“heat sink” in WO2019239997A1) that supports a semiconductor element, a sealing resin (“sealing body” in WO2019239997A1) that covers a portion of the base material and the semiconductor element, and a heat dissipating member (“heat dissipating fin” in WO2019239997A1) that faces the base material. The sealing resin is secured to the heat dissipating member with screws. This semiconductor device, therefore, exhibits improved heat dissipation.

In addition to the semiconductor device disclosed in WO2019239997A1, an alternative semiconductor device can be conceived where a base material is bonded to a heat dissipating member via a bonding layer. This semiconductor device eliminates the process of attaching the sealing resin to the heat dissipating member. However, attaching the heat dissipating member to the base material after the sealing resin is formed may result in deformation of the sealing resin or other undesirable effects, especially if the bonding layer is formed at a relatively high temperature.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a right-side view of the semiconductor device shown in FIG. 1.

FIG. 4 is a front view of the semiconductor device shown in FIG. 1.

FIG. 5 is a rear view of the semiconductor device shown in FIG. 1.

FIG. 6 is a bottom view of the semiconductor device shown in FIG. 1.

FIG. 7 is a plan view corresponding to FIG. 2, with the sealing resin shown as transparent and with the heat dissipating member omitted.

FIG. 8 is a plan view corresponding to FIG. 2, with the sealing resin shown as transparent and with the second conductive member and the heat dissipating member omitted.

FIG. 9 is a plan view corresponding to FIG. 2, with the sealing resin shown as transparent and with the first conductive member, the second conductive member, and the heat dissipating member omitted.

FIG. 10 is a sectional view taken along line X-X in FIG. 7.

FIG. 11 is a sectional view taken along line XI-XI in FIG. 7.

FIG. 12 is an enlarged view of the first semiconductor element shown in FIG. 11, along with its surroundings.

FIG. 13 is an enlarged view of the second semiconductor element shown in FIG. 11, along with its surroundings.

FIG. 14 is a sectional view taken along line XIV-XIV in FIG. 7.

FIG. 15 is a sectional view taken along line XV-XV in FIG. 7.

FIG. 16 is an enlarged view of a portion of FIG. 10.

FIG. 17 is a sectional view of a semiconductor device according to a first variation of the first embodiment and corresponds to FIG. 11.

FIG. 18 is an enlarged sectional view of a semiconductor device according to a second variation of the first embodiment and corresponds to FIG. 16.

FIG. 19 is a sectional view illustrating a manufacturing process of the semiconductor device shown in FIG. 1.

FIG. 20 is a sectional view illustrating a manufacturing process of the semiconductor device shown in FIG. 1.

FIG. 21 is a sectional view illustrating a manufacturing process of the semiconductor device shown in FIG. 1.

FIG. 22 is a sectional view illustrating a manufacturing process of the semiconductor device shown in FIG. 1.

FIG. 23 is a sectional view illustrating a manufacturing process of the semiconductor device shown in FIG. 17.

FIG. 24 is a sectional view illustrating a manufacturing process of the semiconductor device shown in FIG. 17.

FIG. 25 is a schematic view of a vehicle equipped with the semiconductor device shown in FIG. 1.

FIG. 26 is a plan view of a semiconductor device according to a second embodiment of the present disclosure.

FIG. 27 is a sectional view of the semiconductor device shown in FIG. 26 and corresponds to FIG. 10.

FIG. 28 is a sectional view of the semiconductor device shown in FIG. 26 and corresponds to FIG. 11.

FIG. 29 is a partially enlarged sectional view illustrating a manufacturing process of the semiconductor device shown in FIG. 26.

FIG. 30 is a plan view of a semiconductor device according to a third embodiment of the present disclosure.

FIG. 31 is a sectional view of the semiconductor device shown in FIG. 30 and corresponds to FIG. 11.

FIG. 32 is a sectional view of a semiconductor device according to a variation of the third embodiment and corresponds to FIG. 31.

FIG. 33 is a sectional view illustrating a manufacturing process of the semiconductor device shown in FIG. 30.

FIG. 34 is a plan view of a semiconductor device according to a fourth embodiment of the present disclosure.

FIG. 35 is a sectional view of the semiconductor device shown in FIG. 34 and corresponds to FIG. 10.

FIG. 36 is a sectional view of the semiconductor device shown in FIG. 34 and corresponds to FIG. 11.

FIG. 37 is a sectional view illustrating a manufacturing process of the semiconductor device shown in FIG. 34.

FIG. 38 is a sectional view illustrating a manufacturing process of the semiconductor device shown in FIG. 34.

FIG. 39 is a plan view of a semiconductor device according to a fifth embodiment of the present disclosure.

FIG. 40 is a sectional view of the semiconductor device shown in FIG. 39 and corresponds to FIG. 10.

FIG. 41 is a sectional view of the semiconductor device shown in FIG. 39 and corresponds to FIG. 11.

FIG. 42 is a sectional view illustrating a manufacturing process of the semiconductor device shown in FIG. 39.

FIG. 43 is a sectional view illustrating a manufacturing process of the semiconductor device shown in FIG. 39.

### DETAILED DESCRIPTION OF EMBODIMENTS

The following describes details of the present disclosure with reference to the accompanying drawings.

### First Embodiment

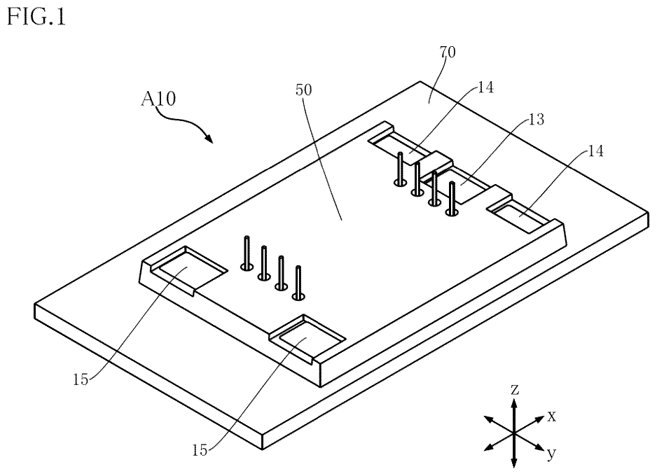

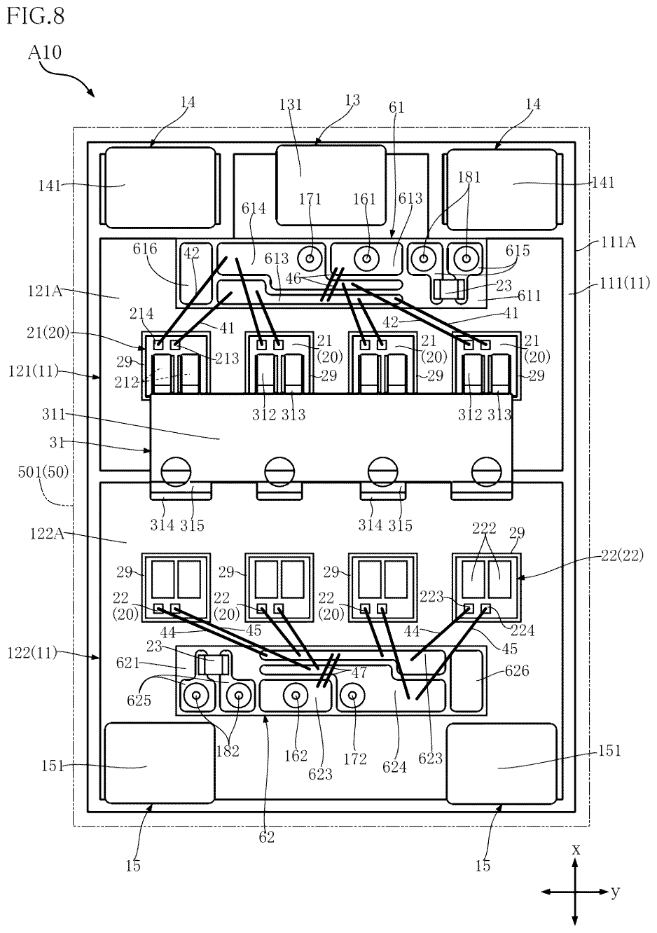

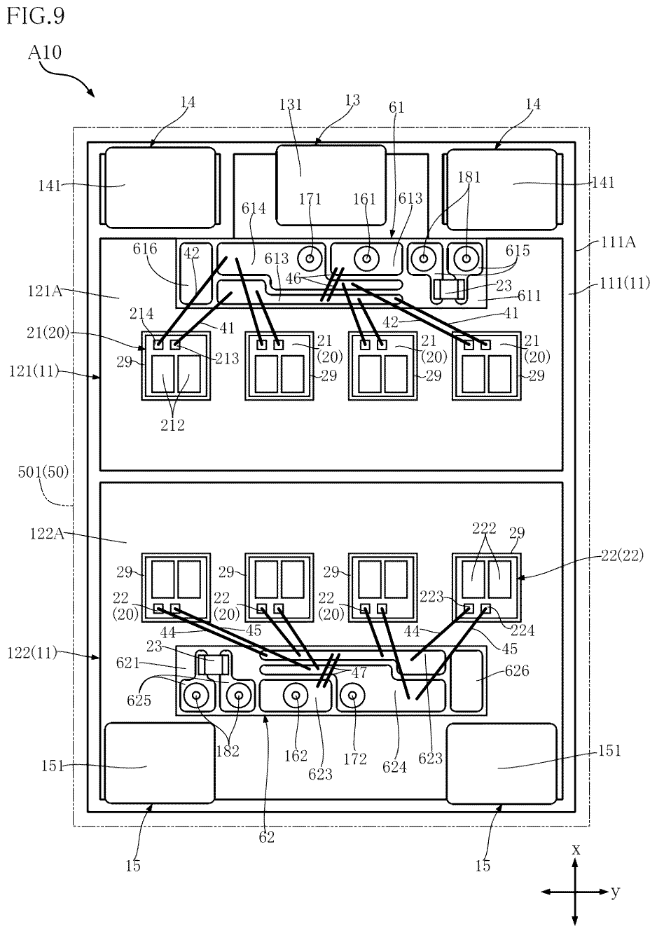

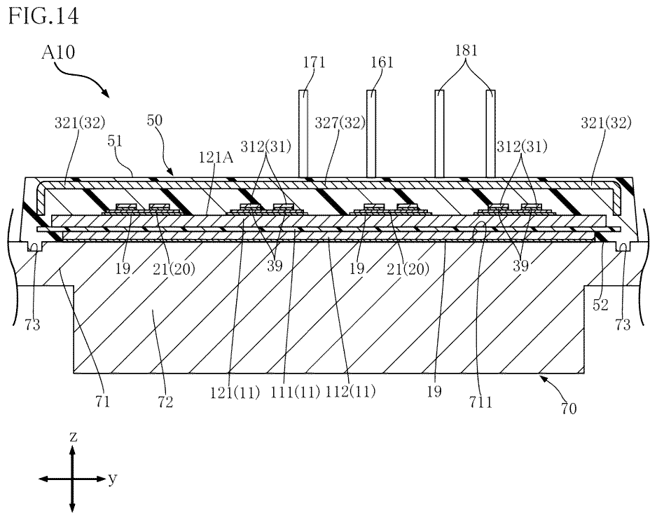

With reference to FIGS. 1 to 16, a semiconductor device A10 according to a first embodiment of the present disclosure will be described. The semiconductor device A10 includes a base material 11, a first bonding layer 19, a first power terminal 13, two second power terminals 14, two third power terminals 15, a plurality of semiconductor elements 20, a first conductive member 31, a second conductive member 32, a second bonding layer 39, a sealing resin 50, and a heat dissipating member 70. The semiconductor device A10 additionally includes a first signal terminal 161, a second signal terminal 162, a third signal terminal 171, a fourth signal terminal 172, two fifth signal terminals 181, two sixth signal terminals 182, two thermistors 23, a first wiring 61, and a second wiring 62. For ease of understanding, FIGS. 7 to 9 show the sealing resin 50 as transparent and omit the illustration of the heat dissipating member 70. In FIGS. 7 to 9, the outside shape of the sealing resin 50 is shown as imaginary lines (dash-double-dot lines). For ease of understanding, FIG. 8 additionally omits the illustration of the second conductive member 32. For ease of understanding, FIG. 9 additionally omits the illustration of each of the first conductive member 31 and the second conductive member 32.

For convenience of the description of the semiconductor device A10, the direction of the normal to the later-described obverse surface 711 of the heat dissipating member 70 is referred to as “first direction z.” A direction perpendicular to the first direction z is referred to as “second direction x.” The direction perpendicular to both the first direction z and the second direction x is referred to as “third direction y.”

The semiconductor device A10 converts the DC power supplied through the first power terminal 13 and the two second power terminals 14 into AC power using the semiconductor elements 20. The resulting AC power is supplied through the third power terminals 15 to a load, such as a motor.

The heat dissipating member 70 is used for cooling the semiconductor device A10. The heat dissipating member 70 contains metal. For example, the heat dissipating member 70 is made of a material containing aluminum (Al).

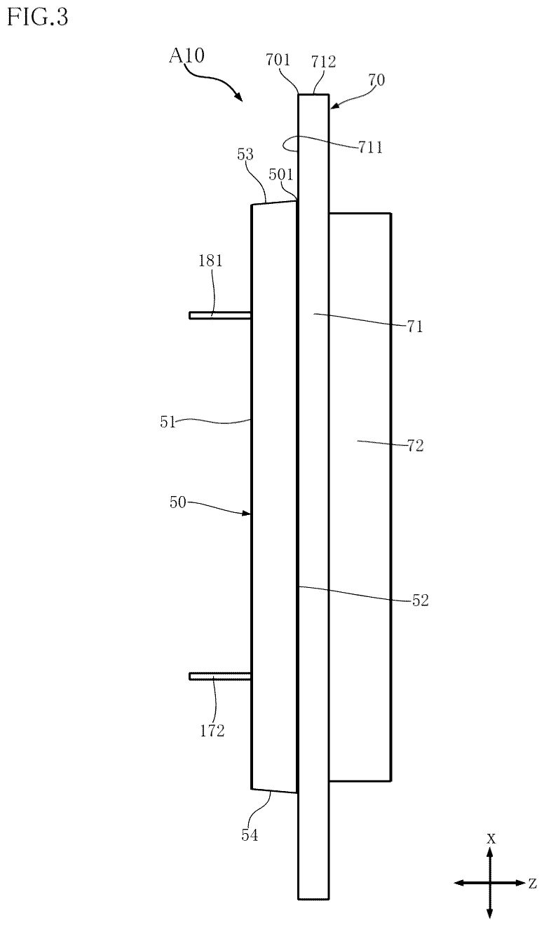

As shown in FIGS. 3 to 5, the heat dissipating member 70 has a base portion 71, an obverse surface 711, a plurality of end surfaces 712, and a heat dissipating portion 72. The base portion 71 has the shape of a flat plate. The obverse surface 711 and the end surfaces 712 are included in the base portion 71. The obverse surface 711 faces a first side in the first direction z. In the semiconductor device A10, the obverse surface 711 is partly exposed from the sealing resin 50. Each end surface 712 faces a direction perpendicular to the first direction z. Each end surface 712 is exposed from the sealing resin 50.

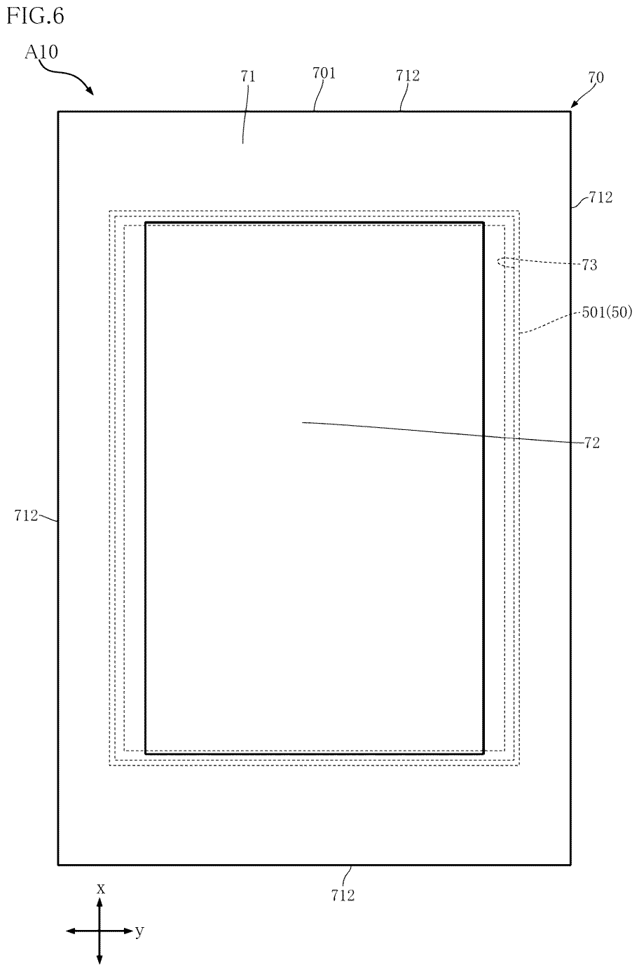

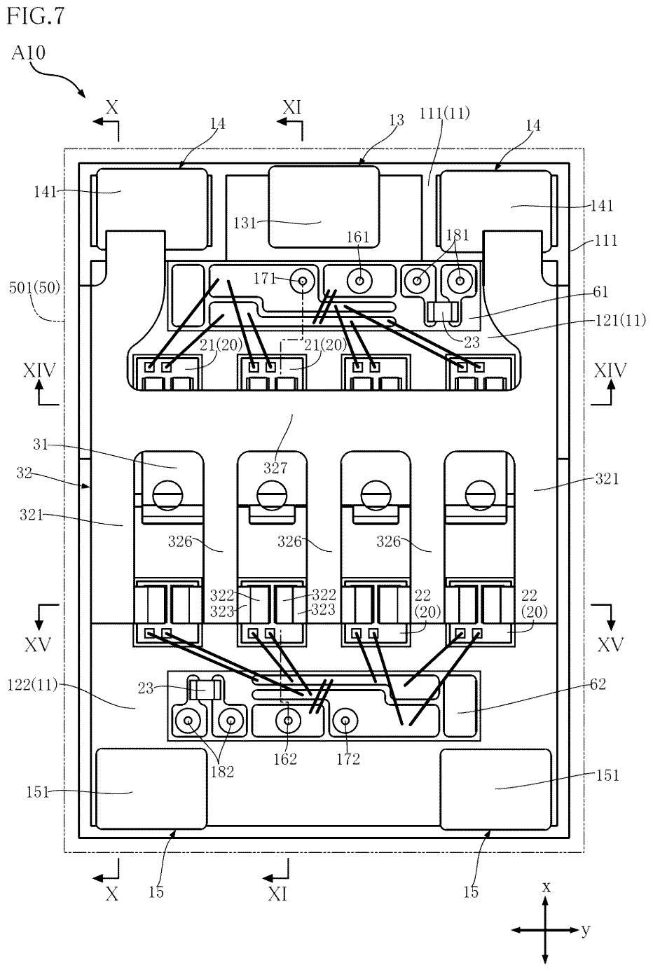

As shown in FIGS. 3 to 5, the heat dissipating portion 72 is connected to the base portion 71. The heat dissipating portion 72 protrudes from the base portion 71 toward the side opposite the obverse surface 711 in the first direction z. In the semiconductor device A10, the heat dissipating portion 72 has the shape of a rectangular parallelepiped. In other examples, the heat dissipating portion 72 may be composed of a plurality of fins arranged along a direction perpendicular to the first direction z. As shown in FIG. 6, the heat dissipating portion 72 is positioned inside the peripheral edge 501 of the sealing resin 50 as viewed in the first direction z.

As shown in FIGS. 6, 10, 11, 14, and 15, the base portion 71 of the heat dissipating member 70 has an engagement portion 73 that is recessed from the obverse surface 711. A portion of the sealing resin 50 is contained in the engagement portion 73.

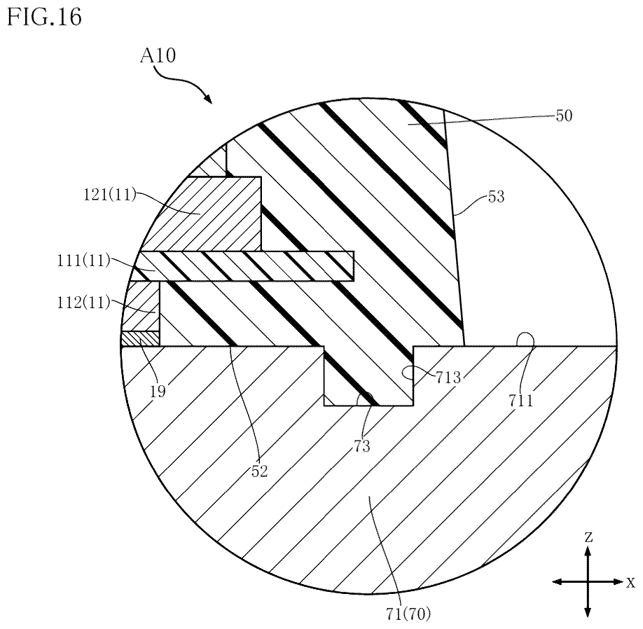

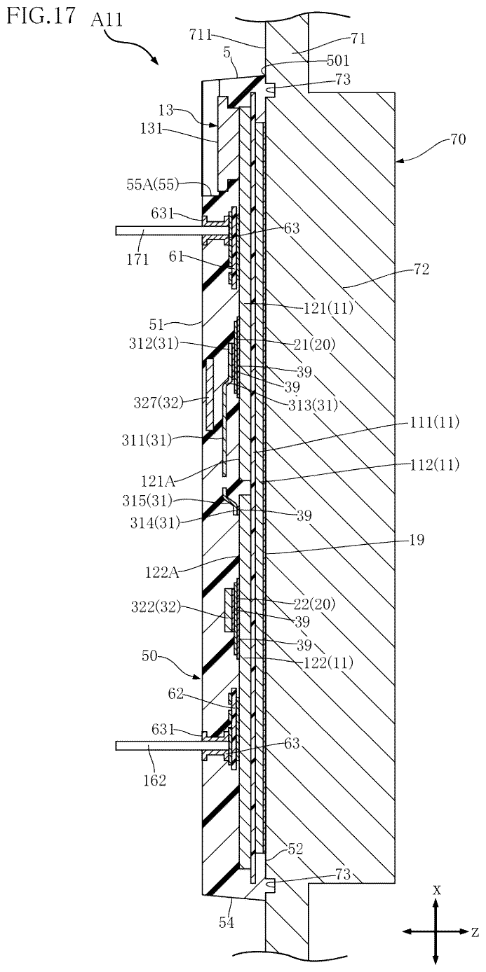

As shown in FIG. 16, the heat dissipating member 70 has an inner peripheral surface 713 that is continuous with the obverse surface 711 and that defines the engagement portion 73. The inner peripheral surface 713 is included in the base portion 71. The sealing resin 50 is in contact with the inner peripheral surface 713.

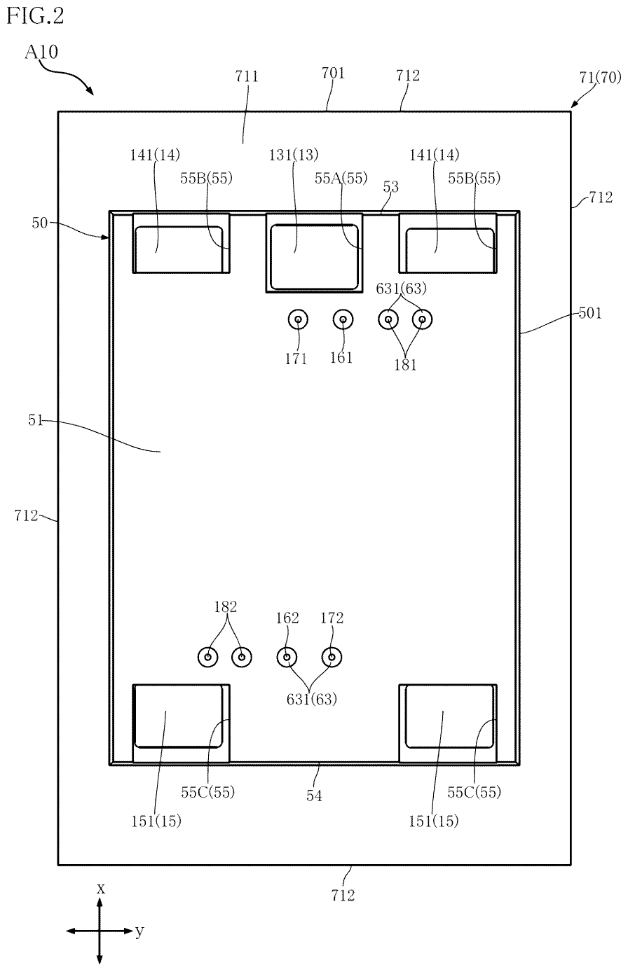

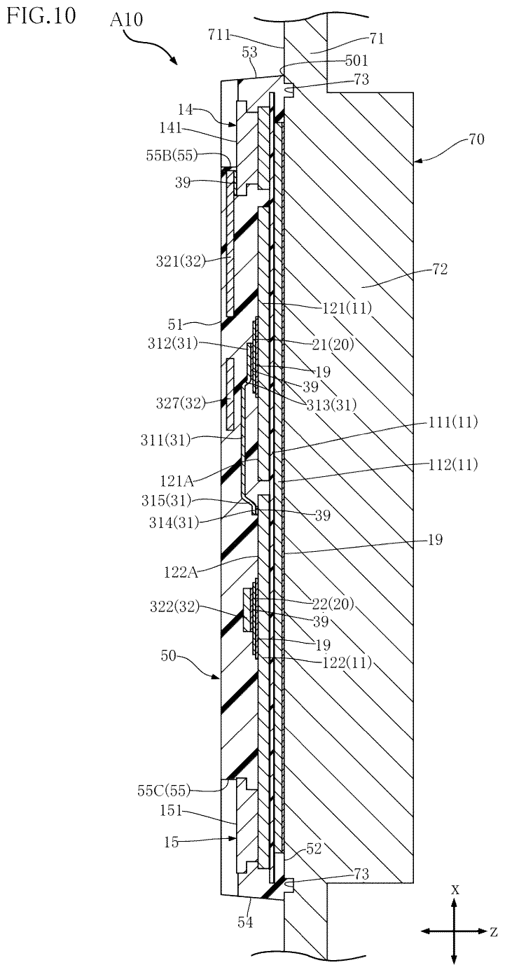

As shown in FIGS. 10, 11, 14, and 15, the sealing resin 50 covers the base material 11, a first conductive layer 121, a second conductive layer 122, the semiconductor elements 20, the first conductive member 31, and the second conductive member 32. The sealing resin 50 also covers a portion of the first power terminal 13, a portion of each third power terminal 15, and a portion of each second power terminal 14. The sealing resin 50 is electrically insulating. The sealing resin 50 is made of a material containing a black epoxy resin, for example. As shown in FIG. 2, the sealing resin 50 is positioned inside the peripheral edge 701 of the heat dissipating member 70 as viewed in the first direction z. As shown in FIGS. 3 to 5, the sealing resin 50 has a top surface 51, a bottom surface 52, a first side surface 53, a second side surface 54, and a plurality of recesses 55.

As shown in FIGS. 10, 11, 14, and 15, the top surface 51 faces the side on which the first conductive layer 121 and the second conductive layer 122 are positioned in the first direction z relative to the base material 11. In short, the top surface 51 faces the same side as the obverse surface 711 of the heat dissipating member 70 in the first direction z. The bottom surface 52 faces away from the top surface 51 in the first direction z. As shown in FIGS. 10, 11, 14, and 15, the bottom surface 52 is in contact with the obverse surface 711.

As shown in FIGS. 3 and 4, the first side surface 53 and the second side surface 54 are spaced apart from each other in the second direction x. The first side surface 53 and the second side surface 54 face away from each other in the second direction x.

As shown in FIGS. 2, 4, and 5, each recess 55 is recessed from the top surface 51 and one of the first side surface 53 and the second side surface 54. The recesses 55 include a first recess 55A, two second recesses 55B, and two third recesses 55C. The first recess 55A and the two second recesses 55B are connected to the first side surface 53. In the third direction y, the first recess 55A is positioned between the two second recesses 55B. The two third recesses 55C are connected to the second side surface 54. The two third recesses 55C are spaced apart from each other in the third direction y.

As shown in FIGS. 10, 11, 14, and 15, the base material 11 is bonded to the obverse surface 711 of the heat dissipating member 70. In the semiconductor device A10, the base material 11 is made from a direct bonded copper (DBC) substrate, for example. The base material 11 includes an insulating layer 111, a metal layer 112, the first conductive layer 121, and the second conductive layer 122. The base material 11 is covered with the sealing resin 50.

As shown in FIGS. 10, 11, 14, and 15, the metal layer 112 is bonded to the obverse surface 711 of the heat dissipating member 70. The metal layer 112 contains copper (Cu). As viewed in the first direction z, the metal layer 112 is positioned inside the peripheral edge 111A of the insulating layer 111.

As shown in FIGS. 10, 11, 14, and 15, the insulating layer 111 is positioned between the metal layer 112 and each of the first conductive layer 121 and the second conductive layer 122 in the first direction z. That is, the insulating layer 111 is positioned between the obverse surface 711 of the heat dissipating member 70 and each of the first conductive layer 121 and the second conductive layer 122. The metal layer 112 is additionally bonded to the insulating layer 111. The insulating layer 111 is made of a material with relatively high thermal conductivity. For example, the insulating layer 111 is made of a ceramic material, such as aluminum nitride (AlN). The insulating layer 111 may alternatively be made of an insulating resin sheet instead of a ceramic material.

As shown in FIGS. 10, 11, 14, and 15, the first conductive layer 121 and the second conductive layer 122 are positioned on the side opposite the metal layer 112 relative to the insulating layer 111. Each of the first conductive layer 121 and the second conductive layer 122 is bonded to the insulating layer 111. As shown in FIGS. 8 and 9, the first conductive layer 121 and the second conductive layer 122 are both positioned inside the peripheral edge 111A of the insulating layer 111. The first conductive layer 121 and the second conductive layer 122 contain copper. The first conductive layer 121 and the second conductive layer 122 are spaced apart from each other in the second direction x. The dimension of each of the first conductive layer 121 and the second conductive layer 122 in the first direction z is larger than the dimension of the insulating layer 111 in the first direction z. The first conductive layer 121 has a first mounting surface 121A that faces the same side as the obverse surface 711 of the heat dissipating member 70 in the first direction z. The first mounting surface 121A faces the semiconductor elements 20. The second conductive layer 122 has a second mounting surface 122A that faces the same side as the first mounting surface 121A in the first direction z.

As shown in FIGS. 10, 11, 14, and 15, the first bonding layer 19 bonds the obverse surface 711 of the heat dissipating member 70 and the metal layer 112. The first bonding layer 19 is covered with the sealing resin 50. The first bonding layer 19 contains metal. The first bonding layer 19 is a sintered compact of metal particles containing silver (Ag), for example. In other examples, the first bonding layer 19 may be a thin metal layer formed at the bonding interface by solid-phase diffusion (hereinafter “solid-phase diffusion layer”). In other examples, the first bonding layer 19 may be a metal layer formed by brazing with silver. The glass transition point of the sealing resin 50 is lower than the melting point of the first bonding layer 19.

As shown in FIGS. 7 to 9, each semiconductor element 20 is disposed on either the first conductive layer 121 or the second conductive layer 122. The semiconductor elements 20 are metal-oxide-semiconductor field-effect transistors (MOSFETs), for example. In other examples, the semiconductor elements 20 may be switching elements such as insulated gate bipolar transistors (IGBTs) or diodes. The description of the semiconductor device A10 is directed to the semiconductor elements 20 that are n-channel, vertical MOSFETs. Each semiconductor element 20 includes a compound semiconductor substrate. The compound semiconductor substrate contains silicon carbide (SiC).

As shown in FIG. 9, the semiconductor elements 20 of the semiconductor device A10 include a plurality of first semiconductor elements 21 and a plurality of second semiconductor elements 22. The second semiconductor elements 22 are identical in configuration to the first semiconductor elements 21. The first semiconductor elements 21 are disposed on the first mounting surface 121A of the first conductive layer 121. The first semiconductor elements 21 are arranged along the third direction y. The second semiconductor elements 22 are disposed on the second mounting surface 122A of the second conductive layer 122. The second semiconductor elements 22 are arranged along the third direction y.

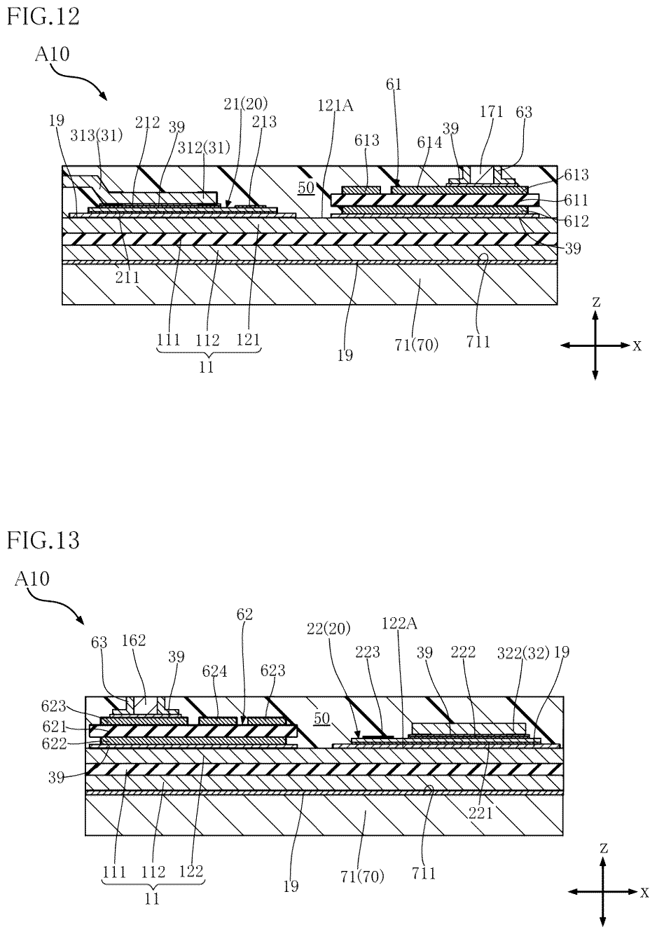

As shown in FIGS. 9 and 12, each first semiconductor element 21 includes a first electrode 211, a second electrode 212, a first gate electrode 213, and a first sensing electrode 214.

As shown in FIG. 12, the first electrode 211 faces the first mounting surface 121A of the first conductive layer 121. The first electrode 211 carries the current corresponding to the power before conversion by the first semiconductor element 21. That is, the first electrode 211 corresponds to the drain electrode of the first semiconductor element 21. The first electrode 211 is electrically bonded to the first mounting surface 121A via a first bonding layer 19. Thus, the first electrode 211 of each first semiconductor element 21 is electrically connected to the first conductive layer 121.

As shown in FIG. 12, the second electrode 212 is positioned on the side opposite the first mounting surface 121A of the first conductive layer 121 in the first direction z. That is, the first electrode 211 and the second electrode 212 are positioned on opposite sides in the first direction z. The second electrode 212 carries the current corresponding to the power after conversion by the first semiconductor element 21. That is, the second electrode 212 corresponds to the source electrode of the first semiconductor element 21.

As shown in FIG. 12, the first gate electrode 213 is positioned on the side opposite the first mounting surface 121A of the first conductive layer 121 in the first direction z. In short, the first gate electrode 213 is positioned on the same side as the second electrode 212 in the first direction z. The first gate electrode 213 receives a gate voltage that drives the first semiconductor element 21. As shown in FIG. 9, the first gate electrode 213 has a smaller area than the second electrode 212 as viewed in the first direction z.

As shown in FIG. 9, the first sensing electrode 214 is positioned on the same side as the second electrode 212 and the first gate electrode 213 in the first direction z. The first sensing electrode 214 is positioned next to the first gate electrode 213 in the third direction y. The first sensing electrode 214 receives the same voltage as that applied to the second electrode 212. As viewed in the first direction z, the first sensing electrode 214 has an area equal to (or substantially equal to) that of the first gate electrode 213.

As shown in FIGS. 9 and 13, each second semiconductor element 22 includes a third electrode 221, a fourth electrode 222, a second gate electrode 223, and a second sensing electrode 224.

As shown in FIG. 13, the third electrode 221 faces the second mounting surface 122A of the second conductive layer 122. The third electrode 221 carries the current corresponding to the power before conversion by the second semiconductor element 22. That is, the third electrode 221 corresponds to the drain electrode of the second semiconductor element 22. The third electrode 221 is electrically bonded to the second mounting surface 122A via a first bonding layer 19. Thus, the third electrode 221 of each second semiconductor element 22 is electrically connected to the second conductive layer 122.

As shown in FIG. 13, the fourth electrode 222 is positioned on the side opposite the second mounting surface 122A of the second conductive layer 122 in the first direction z. That is, the third electrode 221 and the fourth electrode 222 are positioned on opposite sides in the first direction z. The fourth electrode 222 carries the current corresponding to the power after conversion by the second semiconductor element 22. That is, the fourth electrode 222 corresponds to the source electrode of the second semiconductor element 22.

As shown in FIG. 13, the second gate electrode 223 is positioned on the side opposite the second mounting surface 122A of the second conductive layer 122 in the first direction z. In short, the second gate electrode 223 is positioned on the same side as the fourth electrode 222 in the first direction z. The second gate electrode 223 receives a gate voltage that drives the second semiconductor element 22. As shown in FIG. 9, the second gate electrode 223 has a smaller area than the fourth electrode 222 as viewed in the first direction z.

As shown in FIG. 9, the second sensing electrode 224 is positioned on the same side as the fourth electrode 222 and the second gate electrode 223 in the first direction z. The second sensing electrode 224 is positioned next to the second gate electrode 223 in the third direction y. The second sensing electrode 224 receives the same voltage as that applied to the fourth electrode 222. As viewed in the first direction z, the second sensing electrode 224 has an area equal to (or substantially equal to) that of the second gate electrode 223.

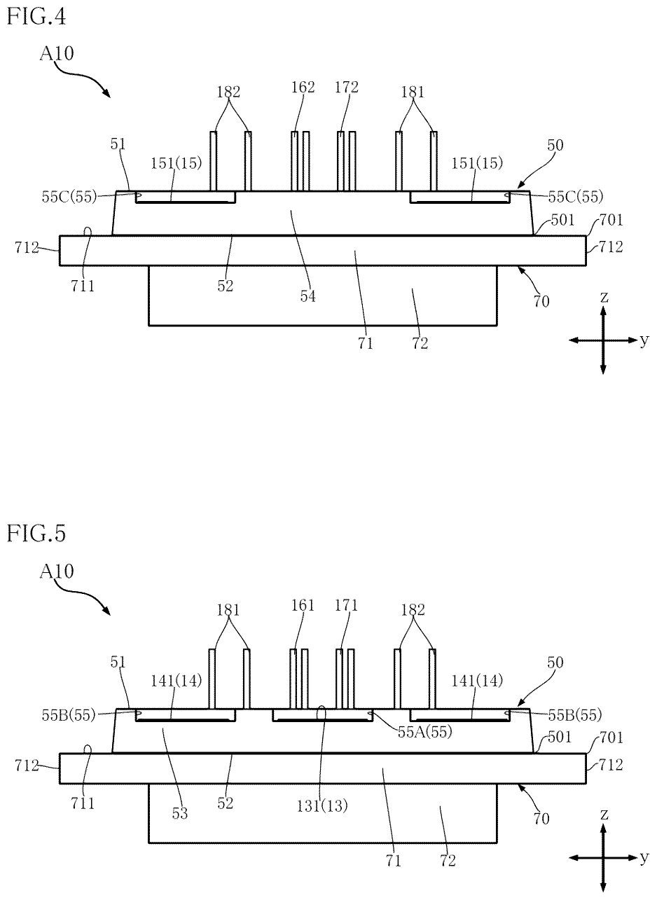

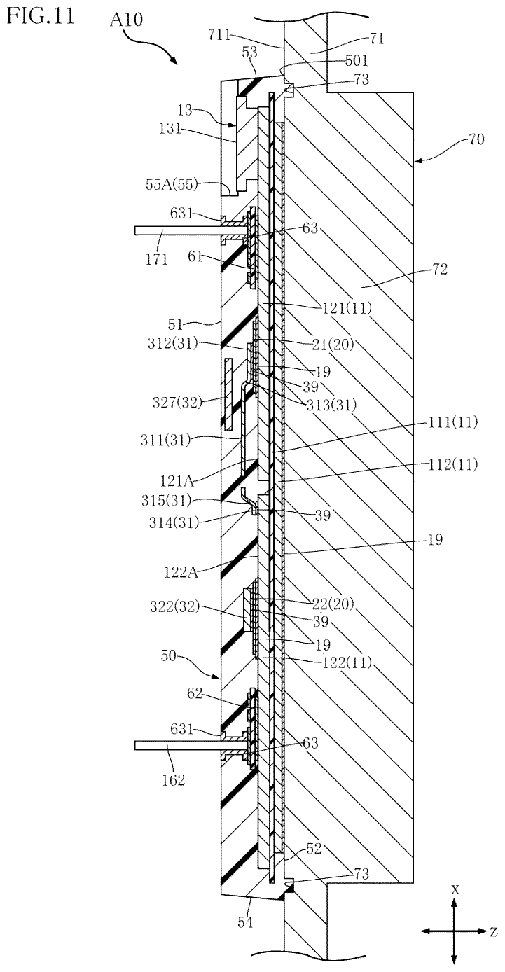

As shown in FIG. 9, the first power terminal 13 is positioned on the side opposite the plurality of second semiconductor elements 22 in the second direction x relative to the plurality of first semiconductor elements 21. The first power terminal 13 is disposed on the base material 11. The first power terminal 13 is electrically bonded to the first conductive layer 121. Thus, the first power terminal 13 is electrically connected to the respective first electrodes 211 of the first semiconductor elements 21 via the first conductive layer 121. The first power terminal 13 is a P terminal (positive terminal) for input of the DC power to be converted. As shown in FIG. 2, the first power terminal 13 is exposed from the top surface 51 of the sealing resin 50. As viewed in the first direction z, the first power terminal 13 is surrounded by the peripheral edge 501 of the sealing resin 50 and positioned inside the peripheral edge of the top surface 51. As shown in FIG. 11, the first power terminal 13 has a first connecting surface 131 that is exposed from the sealing resin 50. The first connecting surface 131 faces the same side as the obverse surface 711 of the heat dissipating member 70 in the first direction z. As shown in FIGS. 5 and 11, in the semiconductor device A10, the first connecting surface 131 is positioned inside the first recess 55A among the plurality of recesses 55 in the sealing resin 50. As an alternative to this configuration of the first power terminal 13 of the semiconductor device A10, the first power terminal 13 may protrude in the second direction x from the first side surface 53 of the sealing resin 50.

As shown in FIG. 9, the two second power terminals 14 are positioned on the same side as the first power terminal 13 in the second direction x relative to the plurality of first semiconductor elements 21. The second power terminals 14 are disposed on the base material 11. The second power terminals 14 are disposed above the insulating layer 111. Each second power terminal 14 is electrically connected to the respective fourth electrodes 222 of the second semiconductor elements 22. The second power terminals 14 are N terminals (negative terminals) for input of the DC power to be converted. The two second power terminals 14 are spaced apart from each other in the third direction y. The first power terminal 13 is positioned between the two second power terminals 14 in the third direction y. As shown in FIG. 2, each second power terminal 14 is exposed from the top surface 51 of the sealing resin 50. As viewed in the first direction z, the two second power terminals 14 are surrounded by the peripheral edge 501 of the sealing resin 50 and positioned inside the peripheral edge of the top surface 51. As shown in FIG. 10, each second power terminal 14 has a second connecting surface 141 that is exposed from the sealing resin 50. The second connecting surface 141 faces the same side as the obverse surface 711 of the heat dissipating member 70 in the first direction z. As shown in FIGS. 5 and 10, in the semiconductor device A10, the two second connecting surfaces 141 are respectively positioned inside the two second recesses 55B among the plurality of recesses 55 in the sealing resin 50. As an alternative to this configuration of the second power terminals 14 of the semiconductor device A10, the second power terminals 14 may each protrude in the second direction x from the first side surface 53 of the sealing resin 50.

As shown in FIG. 9, the two third power terminals 15 are positioned on the side opposite the first power terminal 13 and the two second power terminals 14 in the second direction x relative to the plurality of semiconductor elements 20. The two third power terminals 15 are disposed on the base material 11. The two third power terminals 15 are electrically bonded to the second conductive layer 122. Thus, each third power terminal 15 is electrically connected to the respective third electrodes 221 of the second semiconductor elements 22 via the second conductive layer 122. The AC power converted by the semiconductor elements 20 is output from the two third power terminals 15. In the semiconductor device A10, the two third power terminals 15 are spaced apart from each other in the third direction y. As shown in FIG. 2, each third power terminal 15 is exposed from the top surface 51 of the sealing resin 50. As viewed in the first direction z, the two third power terminals 15 are surrounded by the peripheral edge 501 of the sealing resin 50 and positioned inside the peripheral edge of the top surface 51. As shown in FIG. 10, each third power terminal 15 has a third connecting surface 151 that is exposed from the sealing resin 50. The third connecting surface 151 faces the same side as the obverse surface 711 of the heat dissipating member 70 in the first direction z. As shown in FIGS. 4 and 10, in the semiconductor device A10, the two third connecting surfaces 151 are respectively positioned inside the two third recesses 55C among the plurality of recesses 55 in the sealing resin 50. As an alternative to this configuration of the third power terminals 15 of the semiconductor device A10, the third power terminals 15 may each protrude in the second direction x from the second side surface 54 of the sealing resin 50.

As shown in FIG. 12, the first wiring 61 is bonded to the first mounting surface 121A of the first conductive layer 121. The first wiring 61 is positioned on the side opposite the plurality of second semiconductor elements 22 in the second direction x relative to the plurality of first semiconductor elements 21. The first wiring 61 is electrically connected to the first semiconductor elements 21 and the first conductive layer 121. As shown in FIGS. 9 and 12, the first wiring 61 includes a first mounting layer 611, a first metal layer 612, two first gate wiring layers 613, a first sensing wiring layer 614, a first temperature-sensing wiring layer 615, and a second sensing wiring layer 616.

As shown in FIG. 9, the first mounting layer 611 has disposed thereon the two first gate wiring layers 613, the first sensing wiring layer 614, the two first temperature-sensing wiring layers 615, and the second sensing wiring layer 616. The first mounting layer 611 is an insulator. The first mounting layer 611 is made of a ceramic material, for example. In other examples, the first mounting layer 611 may be made of an insulating resin sheet.

As shown in FIG. 12, the first metal layer 612 is positioned on the side facing the first mounting surface 121A of the first conductive layer 121 in the first direction z relative to the first mounting layer 611. The first metal layer 612 is bonded to the first mounting layer 611. The first metal layer 612 contains copper. The first metal layer 612 is bonded to the first mounting surface 121A via a second bonding layer 39. The second bonding layer 39 contains metal. The second bonding layer 39 is solder. Thus, the second bonding layer 39 contains tin (Sn). In other examples, the second bonding layer 39 may be a sintered compact of metal particles containing silver (Ag), for example. The glass transition point of the sealing resin 50 is lower than the melting point of the second bonding layer 39. In the case where second bonding layer 39 is solder, the melting point of the second bonding layer 39 is lower than that of the first bonding layer 19.

As shown in FIGS. 9 and 12, the two first gate wiring layers 613 are positioned on the side opposite the first metal layer 612 relative to the first mounting layer 611. The first gate wiring layers 613 are bonded to the first mounting layer 611. A plurality of first wires 41 are electrically bonded to one of the two first gate wiring layers 613. Each first wire 41 is electrically bonded to the first gate electrode 213 of a corresponding one of the first semiconductor elements 21. Additionally, each of a plurality of sixth wires 46 is electrically bonded to both of the first gate wiring layers 613. Thus, each first gate wiring layer 613 is electrically connected to the respective first gate electrodes 213 of the first semiconductor elements 21.

As shown in FIGS. 9 and 12, the first sensing wiring layer 614 is positioned on the side opposite the first metal layer 612 relative to the first mounting layer 611. The first sensing wiring layer 614 is bonded to the first mounting layer 611. A plurality of second wires 42 are electrically bonded to the first sensing wiring layer 614. In addition, each second wire 42 is electrically bonded to the first sensing electrode 214 of a corresponding one of the first semiconductor elements 21. Thus, the first sensing wiring layer 614 is electrically connected to the respective first sensing electrodes 214 of the first semiconductor elements 21.

As shown in FIG. 9, the two first temperature-sensing wiring layers 615 are positioned on the side opposite the first metal layer 612 relative to the first mounting layer 611. The two first temperature-sensing wiring layers 615 are bonded to the first mounting layer 611. The two first temperature-sensing wiring layers 615 are next to each other in the third direction y.

As shown in FIG. 9, the second sensing wiring layer 616 is positioned on the side opposite the first metal layer 612 relative to the first mounting layer 611. The second sensing wiring layer 616 is bonded to the first mounting layer 611.

As shown in FIG. 13, the second wiring 62 is bonded to the second mounting surface 122A of the second conductive layer 122. The second wiring 62 is positioned on the side opposite the plurality of first semiconductor elements 21 in the second direction x relative to the plurality of second semiconductor elements 22. The second wiring 62 is electrically connected to the second semiconductor elements 22 and the second conductive layer 122. As shown in FIGS. 9 and 13, the second wiring 62 includes a second mounting layer 621, a second metal layer 622, two second gate wiring layers 623, a third sensing wiring layer 624, two second temperature-sensing wiring layers 625, and a fourth sensing wiring layer 626.

As shown in FIG. 9, the second mounting layer 621 has disposed thereon the two second gate wiring layers 623, the third sensing wiring layer 624, the two second temperature-sensing wiring layers 625, and the fourth sensing wiring layers 626. The second mounting layer 621 is an insulator. The second mounting layer 621 is made of a ceramic material, for example. In other examples, the second mounting layer 621 may be made of an insulating sheet.

As shown in FIG. 13, the second metal layer 622 is positioned on the side facing the second mounting surface 122A of the second conductive layer 122 in the first direction z relative to the second mounting layer 621. The second metal layer 622 is bonded to the second mounting layer 621. The second metal layer 622 contains copper. The second metal layer 622 is bonded to the second mounting surface 122A via a second bonding layer 39.

As shown in FIGS. 9 and 13, the two second gate wiring layers 623 are positioned on the side opposite the second metal layer 622 relative to the second mounting layer 621. The two second gate wiring layers 623 are bonded to the second mounting layer 621. A plurality of fourth wires 44 are electrically bonded to one of the two second gate wiring layers 623. Each fourth wire 44 is electrically bonded to the second gate electrode 223 of a corresponding one of the second semiconductor elements 22. Additionally, each of a plurality of seventh wires 47 is electrically bonded to both of the second gate wiring layers 623. Thus, each second gate wiring layer 623 is electrically connected to the respective second gate electrodes 223 of the second semiconductor elements 22.

As shown in FIGS. 9 and 13, the third sensing wiring layer 624 is positioned on the side opposite the second metal layer 622 relative to the second mounting layer 621. The third sensing wiring layer 624 is bonded to the second mounting layer 621. A plurality of fifth wires 45 are electrically bonded to the third sensing wiring layer 624. In addition, each fifth wire 45 is electrically bonded to the second sensing electrode 224 of a corresponding one of the second semiconductor elements 22. Thus, the third sensing wiring layer 624 is electrically connected to the respective second sensing electrodes 224 of the second semiconductor elements 22.

As shown in FIG. 9, the two second temperature-sensing wiring layers 625 are positioned on the side opposite the second metal layer 622 relative to the second mounting layer 621. The two second temperature-sensing wiring layers 625 are bonded to the second mounting layer 621. The two second temperature-sensing wiring layers 625 are next to each other in the third direction y.

As shown in FIG. 9, the fourth sensing wiring layer 626 is positioned on the side opposite the second metal layer 622 relative to the second mounting layer 621. The fourth sensing wiring layer 626 is bonded to the second mounting layer 621.

As shown in FIGS. 12 and 13, a plurality of sleeves 63 are provided, each of which is electrically bonded to the first wiring 61 or the second wiring 62 via a second bonding layer 39. The second bonding layer 39 is solder, for example. The sleeves 63 are made of a conductive material, such as metal. Each sleeve 63 has a tubular shape extending in the first direction z. As shown in FIGS. 2 and 11, each sleeve 63 has an end surface 631 that faces the same side as the first mounting surface 121A of the first conductive layer 121 in the first direction z. The end surface 631 is exposed from the top surface 51 of the sealing resin 50, which will be described later.

As shown in FIGS. 8 and 9, one of the two thermistors 23 is electrically bonded to the two first temperature-sensing wiring layers 615 of the first wiring 61. As shown in FIGS. 8 and 9, the other of the two thermistors 23 is electrically bonded to the two second temperature-sensing wiring layers 625 of the second wiring 62. The two thermistors 23 are used as temperature sensors of the semiconductor device A10.

As shown in FIG. 3, each of the first signal terminal 161, the second signal terminal 162, the third signal terminal 171, the fourth signal terminal 172, the two fifth signal terminals 181, and the two sixth signal terminals 182 is made of a metal pin extending in the first direction z. These terminals protrude from the top surface 51 of the sealing resin 50, which will be described later. Each terminal is press fitted into one of the sleeves 63. Thus, each terminal is supported by a corresponding sleeve 63 and is electrically connected to the first wiring 61 or the second wiring 62.

As shown in FIG. 9, the first signal terminal 161 is press fitted into the sleeve 63, among the plurality of sleeves 63, that is electrically bonded to one of the first gate wiring layers 613 of the first wiring 61. Thus, the first signal terminal 161 is electrically connected to the respective first gate electrodes 213 of the first semiconductor elements 21 via the two first gate wiring layers 613. The first signal terminal 161 receives a gate voltage that drives the first semiconductor elements 21.

As shown in FIGS. 9 and 11, the second signal terminal 162 is press fitted into the sleeve 63, among the plurality of sleeves 63, that is electrically bonded to one of the two second gate wiring layers 623 of the second wiring 62. Thus, the second signal terminal 162 is electrically connected to the respective second gate electrodes 223 of the second semiconductor elements 22 via the two second gate wiring layers 623. The second signal terminal 162 receives a gate voltage that drives the second semiconductor elements 22.

As shown in FIG. 2, the third signal terminal 171 is positioned next to the first signal terminal 161 in the third direction y. As shown in FIGS. 9 and 11, the third signal terminal 171 is press fitted into the sleeve 63, among the plurality of sleeves 63, that is electrically bonded to the first sensing wiring layer 614 of the first wiring 61. Thus, the third signal terminal 171 is electrically connected to the respective first sensing electrodes 214 of the first semiconductor elements 21 via the first sensing wiring layer 614. The third signal terminal 171 receives the same voltage as that applied to the first sensing electrode 214 of each first semiconductor element 21.

As shown in FIG. 2, the fourth signal terminal 172 is positioned next to the second signal terminal 162 in the third direction y. As shown in FIG. 9, the fourth signal terminal 172 is press fitted into the sleeve 63, among the plurality of sleeves 63, that is electrically bonded to the third sensing wiring layer 624 of the second wiring 62. Thus, the fourth signal terminal 172 is electrically connected to the respective second sensing electrodes 224 of the second semiconductor elements 22 via the third sensing wiring layer 624. The fourth signal terminal 172 receives the same voltage as that applied to the second sensing electrode 224 of each second semiconductor element 22.

As shown in FIG. 2, the two fifth signal terminals 181 are positioned on the side opposite the third signal terminal 171 in the third direction y relative to the first signal terminal 161. The two fifth signal terminals 181 are next to each other in the third direction y. As shown in FIG. 9, the two fifth signal terminals 181 are respectively press fitted into two sleeves 63, among the plurality of sleeves 63, that are electrically bonded to the two first temperature-sensing wiring layers 615 of the first wiring 61. Thus, the two fifth signal terminals 181 are electrically connected to one of the two thermistors 23 that is electrically bonded to the two first temperature-sensing wiring layers 615.

As shown in FIG. 2, the two sixth signal terminals 182 are positioned on the side opposite the fourth signal terminal 172 in the third direction y relative to the second signal terminal 162. The two sixth signal terminals 182 are next to each other in the third direction y. As shown in FIG. 9, the two sixth signal terminals 182 are respectively press fitted into two sleeves 63, among the plurality of sleeves 63, that are electrically bonded to the two second temperature-sensing wiring layers 625 of the second wiring 62. Thus, the two sixth signal terminals 182 are electrically connected to one of the two thermistors 23 that is electrically bonded to the two second temperature-sensing wiring layers 625.

As shown in FIGS. 8 and 12, the first conductive member 31 is electrically bonded to the respective second electrodes 212 of the first semiconductor elements 21 and to the second mounting surface 122A of the second conductive layer 122. Thus, the second electrode 212 of each first semiconductor element 21 is electrically connected to the second conductive layer 122. The first conductive member 31 contains copper. The first conductive member 31 is a metal clip. As shown in FIG. 5, the first conductive member 31 includes a main portion 311, a plurality of first bonding portions 312, a plurality of first connecting portions 313, a second bonding portion 314, and a second connecting portion 315.

The main portion 311 is the body of the first conductive member 31. As shown in FIG. 8, the main portion 311 extends in the third direction y. The main portion 311 spans between the first conductive layer 121 and the second conductive layer 122.

As shown in FIGS. 8 and 12, each first bonding portion 312 is bonded to the second electrode 212 of a corresponding one of the first semiconductor elements 21. Each first bonding portion 312 faces the second electrode 212 of the corresponding first semiconductor element 21.

As shown in FIGS. 8 and 12, each first connecting portion 313 is connected to the main portion 311 and a first bonding portion 312. The first connecting portions 313 are spaced apart from each other in the third direction y. As viewed in the third direction y, each first connecting portion 313 is inclined such that the distance from the first mounting surface 121A of the first conductive layer 121 increases from the first bonding portion 312 toward the main portion 311.

As shown in FIGS. 8 and 11, the second bonding portion 314 is bonded to the second mounting surface 122A of the second conductive layer 122. The second bonding portion 314 faces the second mounting surface 122A. The second bonding portion 314 extends in the third direction y. The dimension of the second bonding portion 314 in the third direction y is equal to the dimension of the main portion 311 in the third direction y.

As shown in FIGS. 8 and 11, the second connecting portion 315 is connected to the main portion 311 and the second bonding portion 314. As viewed in the third direction y, the second connecting portion 315 is inclined such that the distance from the second mounting surface 122A of the second conductive layer 122 increases from the second bonding portion 314 toward the main portion 311. The dimension of the second connecting portion 315 in the third direction y is equal to the dimension of the main portion 311 in the third direction y.

As shown in FIG. 12, a second bonding layer 39 is provided between the second electrode 212 of each first semiconductor element 21 and the corresponding first bonding portion 312. The second bonding layer 39 electrically bonds the first bonding portion 312 and the second electrode 212 of the first semiconductor element 21. The second bonding layer 39 is solder, for example. As shown in FIG. 11, a second bonding layer 39 is provided between the second mounting surface 122A of the second conductive layer 122 and the second bonding portion 314. The second bonding layer 39 electrically bonds the second mounting surface 122A and the second bonding portion 314.

As shown in FIGS. 7 and 13, the second conductive member 32 is electrically bonded to the respective fourth electrodes 222 of the second semiconductor elements 22 and to the two second power terminals 14. Thus, the fourth electrode 222 of each second semiconductor element 22 is electrically connected to the second power terminal 14. The second conductive member 32 contains copper. The second conductive member 32 is a metal clip. As shown in FIG. 7, the second conductive member 32 has two main portions 321, a plurality of third bonding portions 322, a plurality of third connecting portions 323, a plurality of intermediate portions 326, and a cross-beam portion 327.

As shown in FIG. 7, the two main portions 321 are spaced apart from each other in the third direction y. The two main portions 321 extend in the second direction x. As shown in FIG. 10, the two main portions 321 are arranged parallel to the first mounting surface 121A of the first conductive layer 121 and the second mounting surface 122A of the second conductive layer 122. The two main portions 321 are positioned farther from the first mounting surface 121A and the second mounting surface 122A than is the main portion 311 of the first conductive member 31.

As shown in FIG. 7, the intermediate portions 326 are spaced apart from each other in the third direction y and are positioned between the two main portions 321 in the third direction y. Each intermediate portion 326 extends in the second direction x. The dimension of each intermediate portion 326 in the second direction x is smaller than the dimension of each main portion 321 in the second direction x.

As shown in FIG. 13, each third bonding portion 322 is bonded to the second electrode 212 of one of the second semiconductor elements 22. Each third bonding portion 322 faces the fourth electrode 222 of the corresponding second semiconductor element 22.

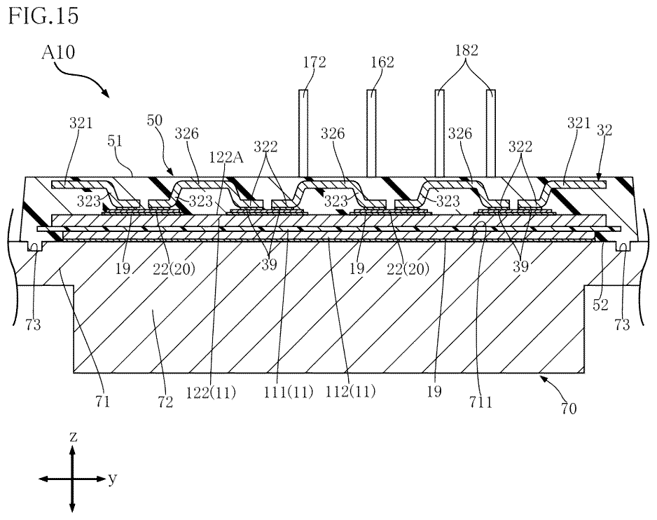

As shown in FIGS. 7 and 15, the third connecting portions 323 are connected to either side of the respective third bonding portions 322 in the third direction y. Each third connecting portion 323 is also connected to one of the two main portions 321 or to one of the intermediate portions 326. As viewed in the second direction x, each third connecting portion 323 is inclined such that the distance from the second mounting surface 122A of the second conductive layer 122 increases from the third bonding portion 322 to the corresponding main portion 321 or intermediate portion 326.

As shown in FIG. 7, the cross-beam portion 327 extends in the third direction y. As shown in FIG. 15, the cross-beam portion 327 includes regions that overlap with the first bonding portions 312 of the first conductive member 31 as viewed in the first direction z. The cross-beam portion 327 is connected at its ends in the third direction y to the two main portions 321.

As shown in FIG. 13, a second bonding layer 39 is provided between the fourth electrode 222 of each second semiconductor element 22 and the corresponding third bonding portion 322. The second bonding layer 39 electrically bonds the third bonding portion 322 and the fourth electrode 222 of the second semiconductor element 22. As shown in FIG. 10, a second bonding layer 39 is provided between each second power terminal 14 and the corresponding main portion 321. The second bonding layer 39 electrically bonds the second power terminal 14 and the main portion 321.

With reference to FIG. 17, the following describes a semiconductor device A11 according to a first variation of the first embodiment of the present disclosure. FIG. 17 corresponds to FIG. 11, which shows the semiconductor device A10. The semiconductor device A11 differs from the semiconductor device A10 in the configuration in which each semiconductor element 20 is electrically bonded to the first conductive layer 121 or the second conductive layer 122.

As shown in FIG. 17, the first electrode 211 of each first semiconductor element 21 is electrically bonded to the first mounting surface 121A of the first conductive layer 121 via a second bonding layer 39. The third electrode 221 of each second semiconductor element 22 is electrically bonded to the second mounting surface 122A of the second conductive layer 122 via a second bonding layer 39.

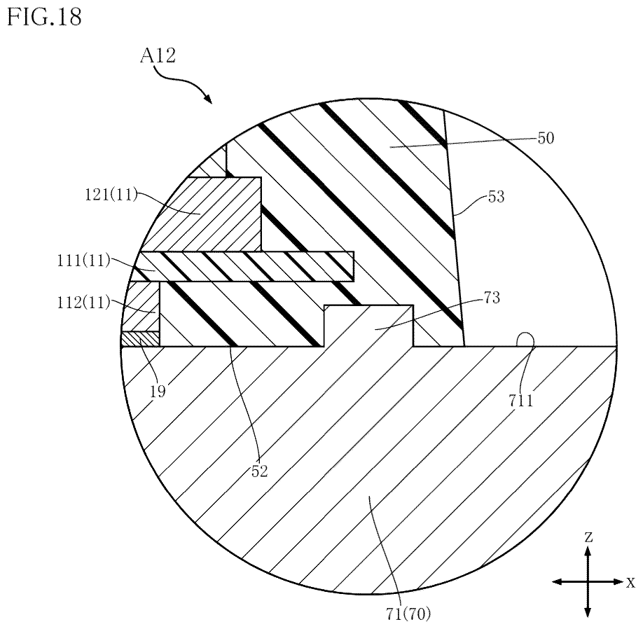

With reference to FIG. 18, the following describes a semiconductor device A12 according to a second variation of the first embodiment of the present disclosure. FIG. 18 corresponds to FIG. 16, which shows the semiconductor device A10. The semiconductor device A12 differs from the semiconductor device A10 in the configuration of the engagement portion 73 of the heat dissipating member 70.

As shown in FIG. 18, the engagement portion 73 projects from the obverse surface 711 of the heat dissipating member 70. The engagement portion 73 projects into the sealing resin 50.

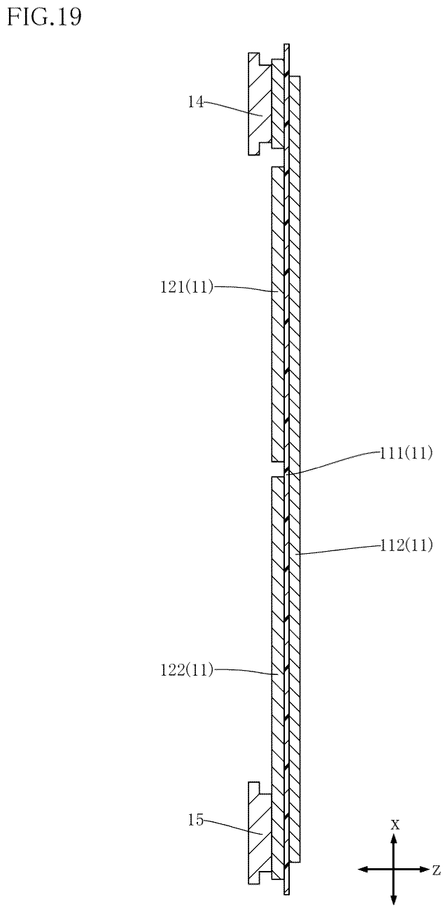

With reference to FIGS. 19 to 22, the following describes an example of a method for manufacturing the semiconductor device A10. FIGS. 19 to 22 correspond to FIG. 10, which shows the semiconductor device A10.

As shown in FIG. 19, the method begins with bonding a first conductive layer 121 and a second conductive layer 122 to the surface of an insulating layer 111 facing the first side in the first direction z. Additionally, a metal layer 112 is bonded to the surface of the insulating layer 111 facing the second side in the first direction z. Subsequently, a first power terminal 13 is electrically bonded to the first conductive layer 121 (see FIG. 11). Two second power terminals 14 are disposed on the insulating layer 111. Two third power terminals 15 are electrically bonded to the second conductive layer 122. This process is performed before at least a fourth process P4, which will be described later.

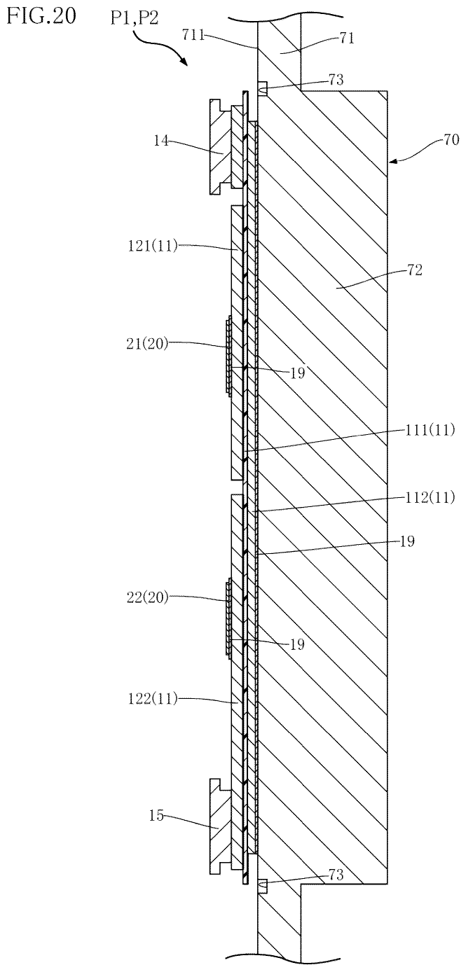

Subsequently, a first process P1 is performed to bond the base material 11 to a heat dissipating member 70 as shown in FIG. 20. In the first process P1, the metal layer 112 is bonded to the obverse surface 711 of the heat dissipating member 70 via a first bonding layer 19. In the first process P1, the first bonding layer 19 is formed at a temperature between 200° C. and 600° C., for example. Subsequently, a second process P2 may be performed to electrically bond each of a plurality of semiconductor elements 20 to the first conductive layer 121 or the second conductive layer 122. In this method of manufacturing the semiconductor device A10, the second process P2 may be concurrently performed with the first process P1. Each semiconductor element 20 is electrically bonded to the first conductive layer 121 or the second conductive layer 122 via a first bonding layer 19. The first bonding layer 19 may be formed by sintering metal particles that contain silver, for example. In other examples, the first bonding layer 19 may be a solid-phase bonding layer. To form the solid-phase bonding layer, pressure is applied to the base material 11 and the semiconductor element 20 toward the obverse surface 711 of the heat dissipating member 70 in the first direction z.

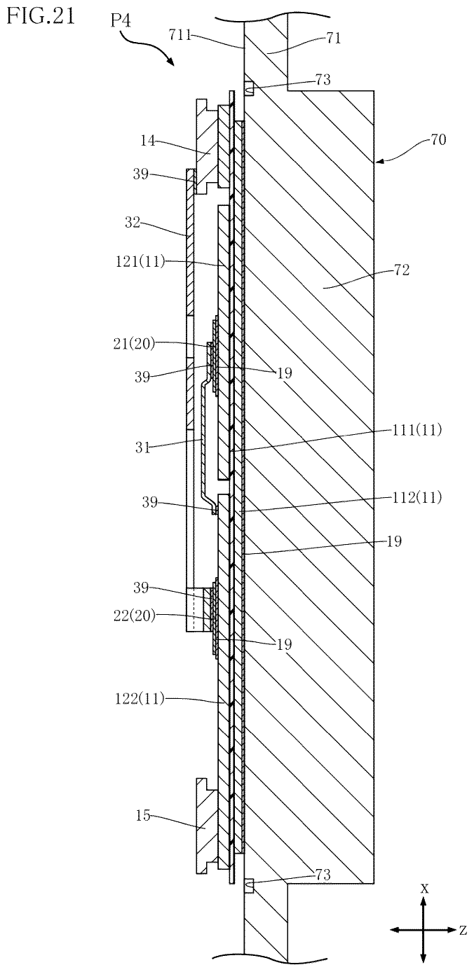

Subsequently, a fourth process P4 is performed to electrically bond each of the first conductive member 31 and the second conductive member 32 as shown in FIG. 21. In the fourth process P4, the first conductive member 31 is electrically bonded to each of the first semiconductor elements 21 and the second conductive layer 122 via a second bonding layer 39. Additionally, the second conductive member 32 is electrically bonded to each of the second semiconductor elements 22 and the two second power terminals 14 via a second bonding layer 39. In the fourth process P4, a first wiring 61, which has a thermistor 23 and a plurality of sleeves 63 electrically bonded thereto, is bonded to the first conductive layer 121 via a second bonding layer 39 (see FIG. 11). Additionally, a second wiring 62, which has a thermistor 23 and a plurality of sleeves 63 electrically bonded thereto, is bonded to the second conductive layer 122 via a second bonding layer 39 (see FIG. 11). Although not shown in the figure, the fourth process P4 additionally includes forming a plurality of first wires 41, second wires 42, fourth wires 44, fifth wires 45, sixth wires 46, and seventh wires 47. In the fourth process P4, the second bonding layer 39 is formed at a temperature of about 260° C., for example. The second bonding layer 39 is formed by reflowing solder and subsequently solidifying the solder.

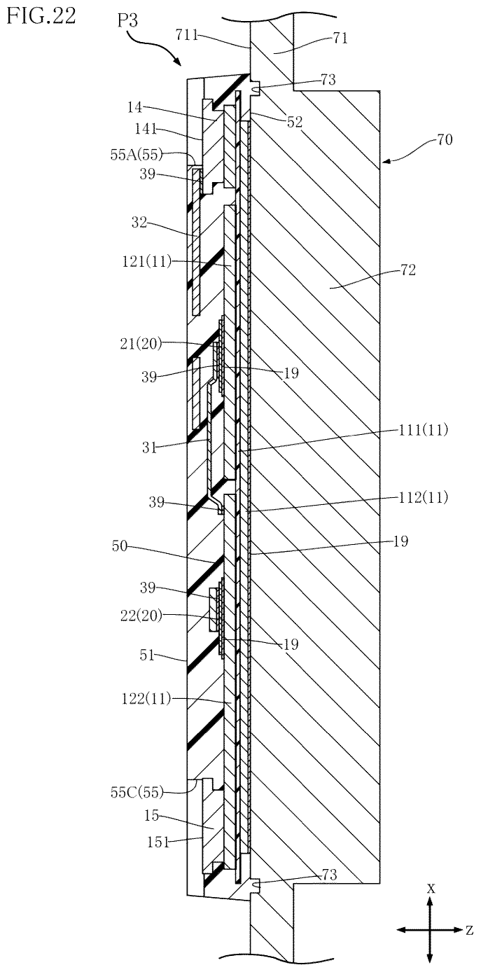

Subsequently, a third process P3 is performed to form a sealing resin 50 that covers the semiconductor elements 20 as shown in FIG. 22. The third process P3 is performed such that the sealing resin 50 covers the base material 11, the first conductive member 31, and the second conductive member 32. The sealing resin 50 is formed by transfer molding. The third process P3 is performed after completion of each of the first process P1, the second process P2, and the fourth process P4. In the third process P3, the sealing resin 50 is formed at a temperature of about 180° C., for example. In other words, the temperature at which the sealing resin 50 is formed in the third process P3 is lower than both the temperature at which the first bonding layer 19 is formed in the first process P1 and the temperature at which the second bonding layer 39 is formed in the fourth process P4. The third process P3 is performed such that the bottom surface 52 of the sealing resin 50 is in contact with the obverse surface 711 of the heat dissipating member 70. In addition, the end surfaces 712 of the heat dissipating member 70 are exposed from the sealing resin 50. In addition, the sealing resin 50 is positioned inside the peripheral edge 701 of the heat dissipating member 70 as viewed in the first direction z.

As shown in FIG. 22, the third process P3 is performed such that the first power terminal 13, the two second power terminals 14, and the two third power terminals 15 are exposed from the top surface 51 of the sealing resin 50. In addition, the sealing resin 50 is received in the engagement portion 73 in the heat dissipating member 70.

Lastly, a first signal terminal 161, a second signal terminal 162, a third signal terminal 171, a fourth signal terminal 172, two fifth signal terminals 181, and two sixth signal terminals 182 are fitted into the respective sleeves 63. As a result, the signal terminals protrude from the top surface 51 of the sealing resin 50. This process is performed after completion of the third process P3. Through the above processes, the semiconductor device A10 is produced.

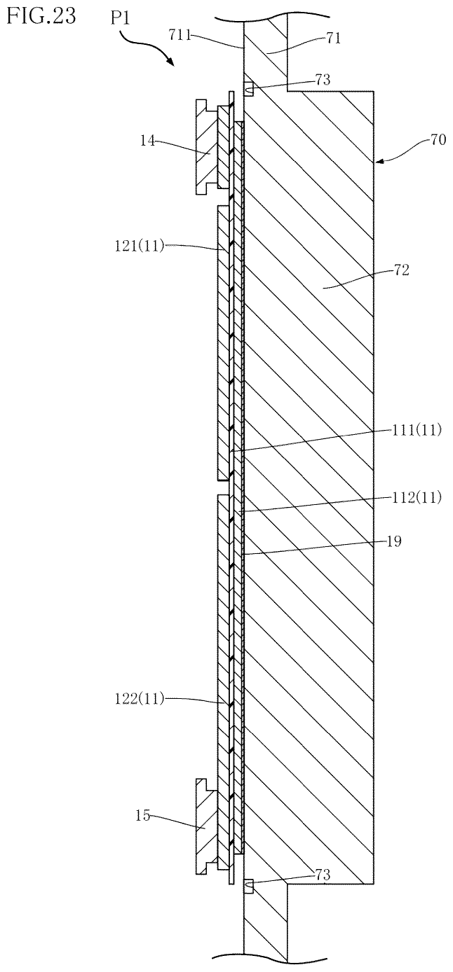

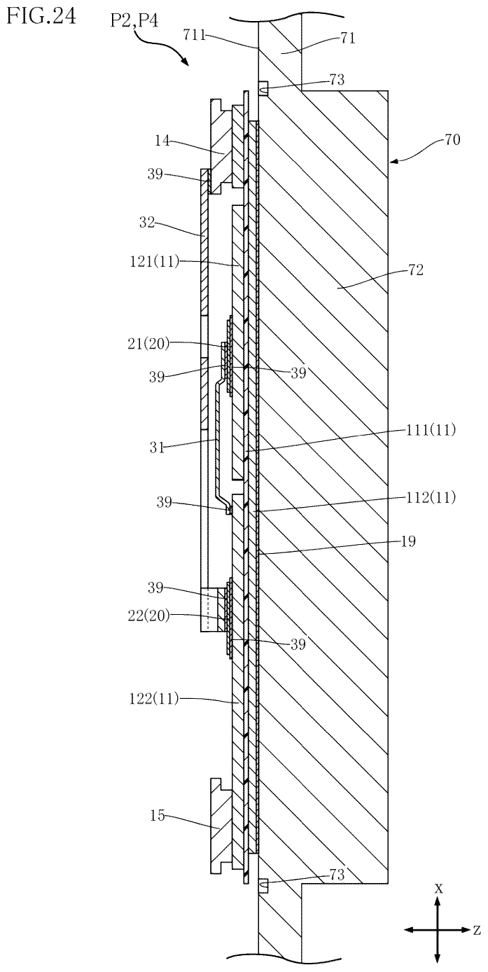

With reference to FIGS. 23 and 24, the following describes an example of a method for manufacturing the semiconductor device A11. FIGS. 23 to 24 correspond to FIG. 10, which shows the semiconductor device A10. The method for manufacturing the semiconductor device A11 differs from that for the semiconductor device A10 in the order in which the first process P1, the second process P2, and the fourth process P4 are performed.

The first process P1 shown in FIG. 23 is performed after completion of the process shown in FIG. 19. After completion of the first process P1, the second process P2 and the fourth process P4 are concurrently performed as shown in FIG. 24. Each semiconductor element 20 is electrically bonded to either the first conductive layer 121 or the second conductive layer 122 via a second bonding layer 39. After completion of the second process P2 and the fourth process P4, the third process P3 shown in FIG. 22 is performed.

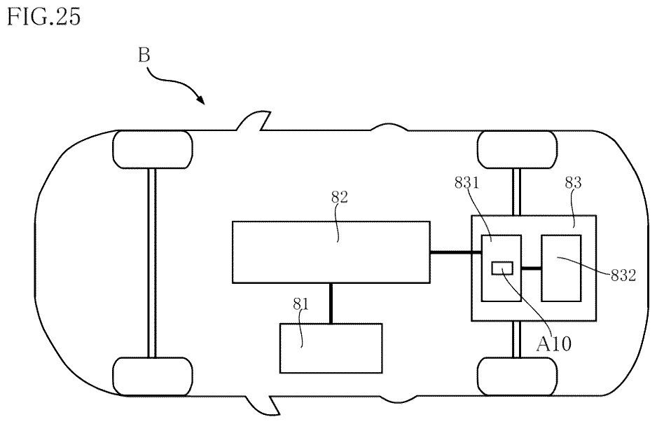

With reference to FIG. 25, the following describes a vehicle B equipped with the semiconductor device A10. The vehicle B is an electric vehicle (EV), for example.

As shown in FIG. 25, the vehicle B includes an on-board charger 81, a storage battery 82, and a drive system 83. The on-board charger 81 wirelessly receives power from an outdoor power supply facility (not shown). Alternatively, the on-board charger 81 may receive power via a wired connection. The on-board charger 81 includes a step-up DC-DC converter. The converter increases the voltage inputted to the on-board charger 81 and supplies the resulting power to the storage battery 82. The voltage is increased to 600 V, for example.

The drive system 83 propels the vehicle B. The drive system 83 includes an inverter 831 and a drive source 832. The semiconductor device A10 forms part of the inverter 831. The power stored in the storage battery 82 is supplied to the inverter 831. The storage battery 82 supplies DC power to the inverter 831. Unlike the power system shown in FIG. 25, an additional step-up DC-DC converter may be provided between the storage battery 82 and the inverter 831. The inverter 831 converts the DC power to AC power. The inverter 831, including the semiconductor device A10, is electrically connected to the drive source 832. The drive source 832 includes an AC motor and a transmission. When AC power from the inverter 831 is supplied to the drive source 832, the AC motor rotates and delivers the torque to the transmission. The transmission reduces the rotational speed transmitted from the AC motor as needed, and rotates the axle of the vehicle B. As a result, the vehicle B is driven. While the vehicle B is being driven, the rotational speed of the AC motor needs to be adjusted based on the position of the accelerator pedal and other relevant information. The inverter 831 including the semiconductor device A10 is used to adjust the frequency of the AC power to match the rotational speed of the AC motor as needed.

The following describes effects of the method for manufacturing the semiconductor device A10 and of related aspects.

The method for manufacturing the semiconductor device A10 includes the first process P1, the second process P2, and the third process P3. The first process P1 includes bonding the base material 11, which includes the insulating layer 111, the first conductive layer 121, and the second conductive layer 122, to the heat dissipating member 70. The second process P2 includes bonding each semiconductor element 20 to either the first conductive layer 121 or the second conductive layer 122. The third process P3 includes forming the sealing resin 50 to cover the semiconductor elements 20. In the first process P1, the base material 11 is bonded to the heat dissipating member 70 such that the insulating layer 111 is positioned between the heat dissipating member 70 and each of the first conductive layer 121 and the second conductive layer 122. The third process P3 is performed after completion of each of the first process P1 and the second process P2. In this method, the first process P1 is completed by the time of the third process P3, ensuring that the semiconductor device A10 being processed is not exposed, in processes subsequent to the third process P3, to temperatures higher than the temperature at which the sealing resin 50 is formed. Consequently, this method for manufacturing the semiconductor device A10, which includes the base material 11 bonded to the heat dissipating member 70, ensures that the shape of the sealing resin 50 is more reliably retained.

The first process P1 includes bonding the base material 11 to the obverse surface 711 of the heat dissipating member 70 via a first bonding layer 19. The temperature at which the sealing resin 50 is formed in the third process P3 is lower than the temperature at which the first bonding layer 19 is formed in the first process P1. This configuration prevents the first bonding layer 19 from melting when the sealing resin 50 is formed.

The method for manufacturing the semiconductor device A10 additionally includes the fourth process P4 of electrically bonding the second conductive member 32 to each relevant semiconductor element 20 (each second semiconductor element 22) via a second bonding layer 39. The fourth process P4 is performed before the third process P3. The temperature at which the sealing resin 50 is formed in the third process P3 is lower than the temperature at which the second bonding layer 39 is formed in the fourth process P4. This configuration prevents the second bonding layer 39 from melting during formation when the sealing resin 50 is formed.

The third process P3 is performed such that the sealing resin 50 is in contact with the obverse surface 711 of the heat dissipating member 70. Additionally, the sealing resin 50 covers the base material 11, and the end surfaces 712 of the heat dissipating member 70 are exposed from the sealing resin 50. In addition, the sealing resin 50 is positioned inside the peripheral edge 701 of the heat dissipating member 70 as viewed in the first direction z. This configuration allows the third process P3 of forming the sealing resin 50 to be performed by pressing a molding die against the heat dissipating member 70 without a gap. As a result, the sealing resin 50 is molded with higher quality.

The semiconductor device A10 additionally includes the first power terminal 13 that is electrically connected to the relevant semiconductor elements 20 (the first semiconductor elements 21). The first power terminal 13 is exposed from the top surface 51 of the sealing resin 50. As viewed in the first direction z, the first power terminal 13 is positioned inside the peripheral edge of the top surface 51. This configuration provides a longer creepage distance from the first power terminal 13 to the heat dissipating member 70 (the distance along the surface of the sealing resin 50). This serves to increase the dielectric withstand voltage of the semiconductor device A10.

The heat dissipating member 70 has the engagement portion 73 that is recessed from the obverse surface 711. The third process P3 is performed such that the sealing resin 50 is received in the engagement portion 73. As a result, the sealing resin 50 produces an anchoring effect, firmly engaging with the heat dissipating member 70. This helps prevent delamination of the sealing resin 50 from the obverse surface 711.

The semiconductor device A10 additionally includes the first signal terminal 161 that is electrically connected to the relevant semiconductor elements 20 (the first semiconductor elements 21). The first signal terminal 161 is exposed from the top surface 51 of the sealing resin 50. This provides a longer creepage distance from the first signal terminal 161 to the heat dissipating member 70.

Second Embodiment:

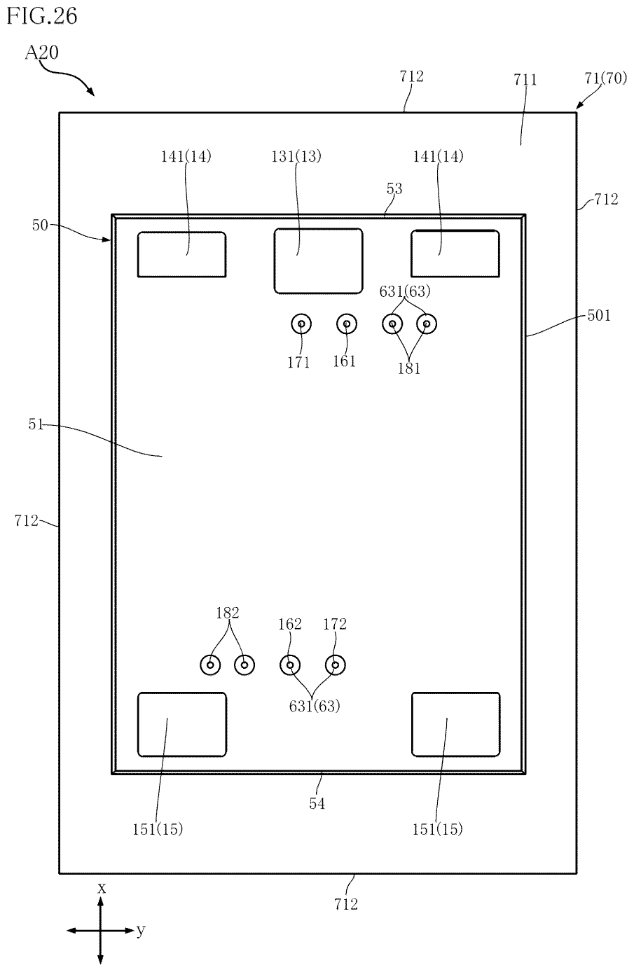

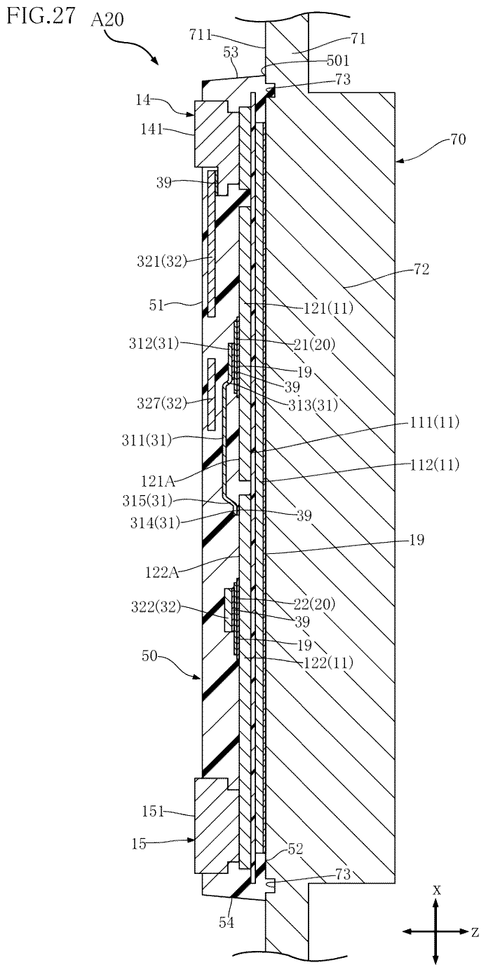

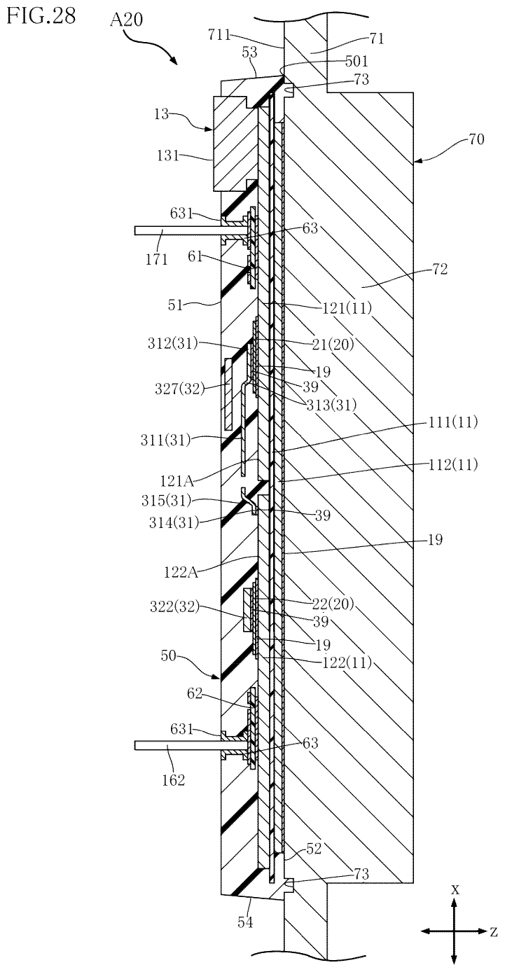

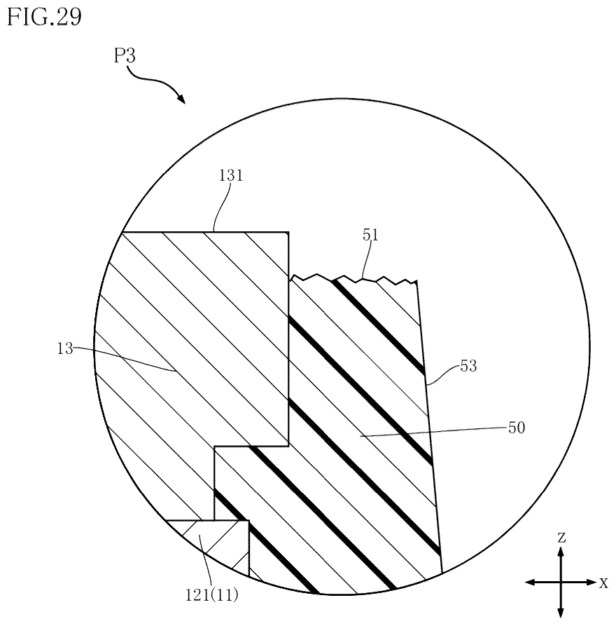

With reference to FIGS. 26 to 28, a semiconductor device A20 according to a second embodiment of the present disclosure will be described. In these figures, elements that are identical or similar to those of the semiconductor device A10 described above are indicated by the same reference numerals, and redundant descriptions are omitted. FIG. 27 corresponds to FIG. 10, which shows the semiconductor device A10. FIG. 28 corresponds to FIG. 11, which shows the semiconductor device A10.

The semiconductor device A20 differs from the semiconductor device A10 in the configurations of the first power terminal 13, the two second power terminals 14, the two third power terminals 15, and the sealing resin 50.

As shown in FIGS. 26 to 28, the first power terminal 13, the two second power terminals 14, and the two third power terminals 15 protrude from the top surface 51 of the sealing resin 50. The sealing resin 50 is not formed with the plurality of recesses 55. The first connecting surface 131 of the first power terminal 13, the second connecting surface 141 of each of the two second power terminals 14, and the third connecting surface 151 of each of the two third power terminals 15 are positioned on the side opposite the bottom surface 52 of the sealing resin 50 relative to the top surface 51 in the first direction z.

With reference to FIG. 29, the following describes an example of a method for manufacturing the semiconductor device A20. FIG. 29 is an enlarged view of a portion of FIG. 28, which shows the semiconductor device A20.

The method for manufacturing the semiconductor device A20 differs from that for the semiconductor device A10 in the third process P3.

As shown in FIG. 29, the third process P3 includes, after the sealing resin 50 is formed, removing a portion of the sealing resin 50 that is positioned on the first side in the first direction z, for example, by wet blasting. As a result of this process, the first power terminal 13, the two second power terminals 14, and the two third power terminals 15 protrude from the top surface 51 of the sealing resin 50. Additionally, the top surface 51 of the sealing resin 50 is made rougher than the first side surface 53 of the sealing resin 50.

The following describes effects of the method for manufacturing the semiconductor device A20 and of related aspects.

The method for manufacturing the semiconductor device A20 includes the first process P1, the second process P2, and the third process P3. The first process P1 includes bonding the base material 11, which includes the insulating layer 111, the first conductive layer 121, and the second conductive layer 122, to the heat dissipating member 70. The second process P2 includes bonding each semiconductor element 20 to either the first conductive layer 121 or the second conductive layer 122. The third process P3 includes forming the sealing resin 50 to cover the semiconductor elements 20. In the first process P1, the base material 11 is bonded to the heat dissipating member 70 such that the insulating layer 111 is positioned between the heat dissipating member 70 and each of the first conductive layer 121 and the second conductive layer 122. The third process P3 is performed after completion of each of the first process P1 and the second process P2. Consequently, this method for manufacturing the semiconductor device A20, which includes the base material 11 bonded to the heat dissipating member 70, ensures that the shape of the sealing resin 50 is more reliably retained. Additionally, the method for manufacturing the semiconductor device A20 has a configuration in common with the method for manufacturing the semiconductor device A10, thereby achieving the same effect as the method for manufacturing the semiconductor device A10.

In the semiconductor device A20, a portion of the first power terminal 13 protrudes from the top surface 51 of the sealing resin 50. This configuration facilitates the process of connecting an external connection component, such as a busbar, to the first connecting surface 131 of the first power terminal 13.

In the case described above, the top surface 51 of the sealing resin 50 is rougher than the first side surface 53 of the sealing resin 50. This configuration allows the third process P3 to be performed so that a portion of the first power terminal 13 protrudes from the top surface 51 without interfering with the molding die.

Third Embodiment:

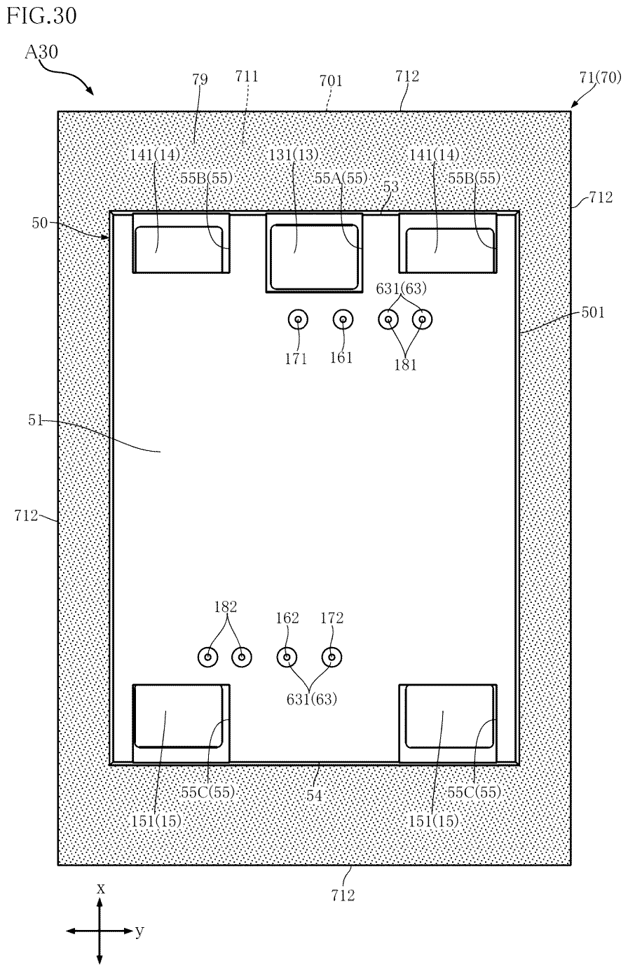

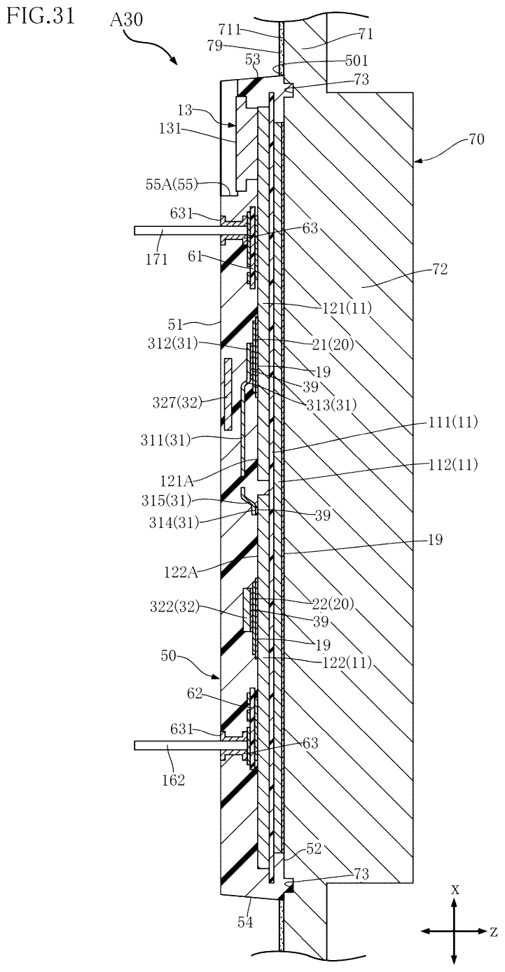

With reference to FIGS. 30 and 31, a semiconductor device A30 according to a third embodiment of the present disclosure will be described. In these figures, elements that are identical or similar to those of the semiconductor device A10 described above are indicated by the same reference numerals, and redundant descriptions are omitted. FIG. 31 corresponds to FIG. 11, which shows the semiconductor device A10.

The semiconductor device A30 differs from the semiconductor device A10 in that it additionally includes a protective layer 79.

As shown in FIGS. 30 and 31, the protective layer 79 covers a portion of the obverse surface 711 of the heat dissipating member 70. The protective layer 79 is an insulator. The protective layer 79 is made of a material containing at least either resin or a ceramic material. As viewed in the first direction z, the protective layer 79 lies outside the sealing resin 50.

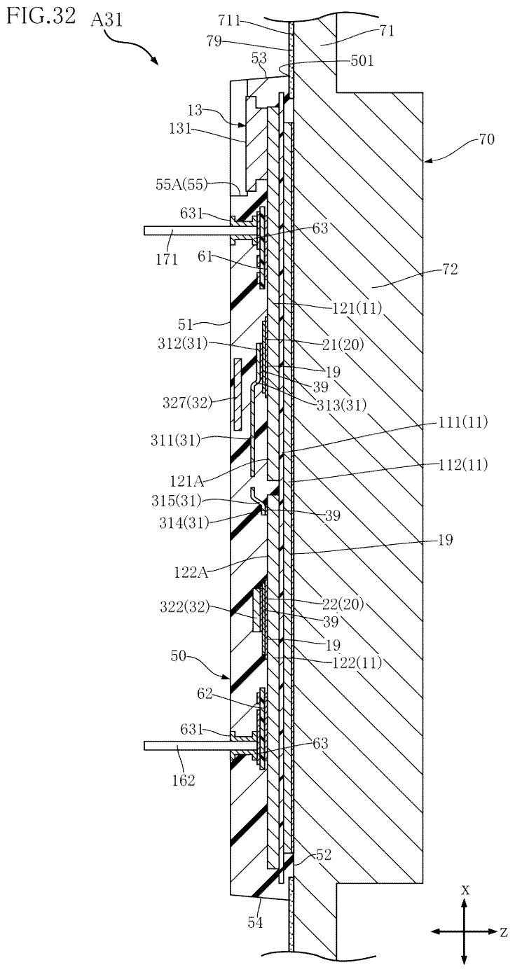

With reference to FIG. 32, the following describes a semiconductor device A31 according to a variation of the third embodiment of the present disclosure. FIG. 32 corresponds to FIG. 31, which shows the semiconductor device A30. The semiconductor device A31 differs from the semiconductor device A30 in the configuration of the protective layer 79.

As shown in FIG. 32, a portion of the protective layer 79 lies between the obverse surface 711 of the heat dissipating member 70 and the sealing resin 50 in the first direction z. As viewed in the first direction z, the protective layer 79 lies outside the metal layer 112 and overlaps with the insulating layer 111. In the semiconductor device A31, the heat dissipating member 70 is not provided with the engagement portion 73.

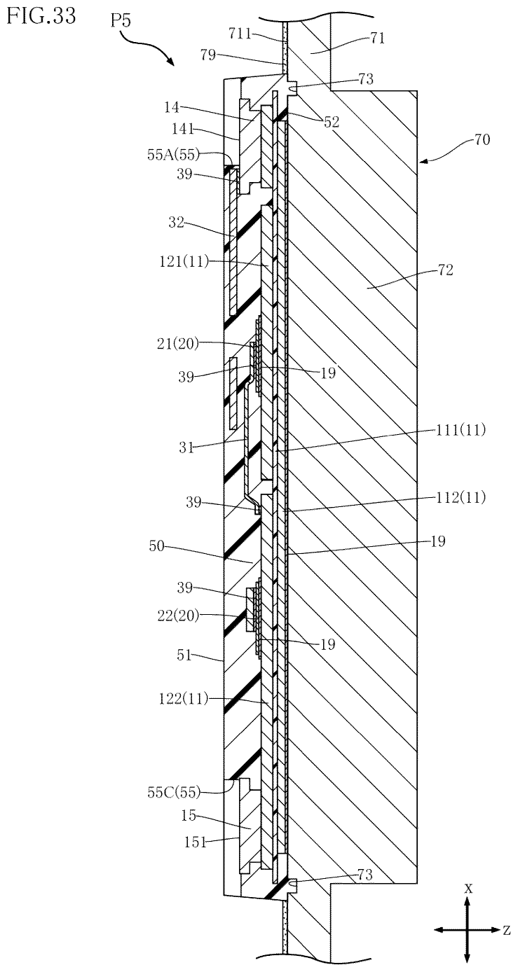

With reference to FIG. 33, the following describes an example of a method for manufacturing the semiconductor device A30. FIG. 33 corresponds to FIG. 10, which shows the semiconductor device A10.

The method for manufacturing the semiconductor device A30 includes a fifth process P5 in addition to the processes of the method for manufacturing the semiconductor device A10.

After completion of the third process P3 shown in FIG. 22, the fifth process P5 is performed to form a protective layer 79 that covers a portion of the obverse surface 711 of the heat dissipating member 70 as shown in FIG. 33. The fifth process P5 is performed such that the protective layer 79 lies outside the sealing resin 50 as viewed in the first direction z. Note that the fifth process P5 may be performed before the third process P3. Through this process, the semiconductor device A31 is produced. The fifth process P5 in this order is performed such that the protective layer 79 lies outside the metal layer 112 as viewed in the first direction z.

The following describes effects of the method for manufacturing the semiconductor device A30 and of related aspects.

The method for manufacturing the semiconductor device A30 includes the first process P1, the second process P2, and the third process P3. The first process P1 includes bonding the base material 11, which includes the insulating layer 111, the first conductive layer 121, and the second conductive layer 122, to the heat dissipating member 70. The second process P2 includes bonding each semiconductor element 20 to either the first conductive layer 121 or the second conductive layer 122. The third process P3 includes forming the sealing resin 50 to cover the semiconductor elements 20. In the first process P1, the base material 11 is bonded to the heat dissipating member 70 such that the insulating layer 111 is positioned between the heat dissipating member 70 and each of the first conductive layer 121 and the second conductive layer 122. The third process P3 is performed after completion of each of the first process P1 and the second process P2. Consequently, this method for manufacturing the semiconductor device A30, which includes the base material 11 bonded to the heat dissipating member 70, ensures that the shape of the sealing resin 50 is more reliably retained. Additionally, the method for manufacturing the semiconductor device A30 has a configuration in common with the method for manufacturing the semiconductor device A10, thereby achieving the same effect as the method for manufacturing the semiconductor device A10.

The method for manufacturing the semiconductor device A30 additionally includes the fifth process P5 of forming the protective layer 79 that is an insulator and that covers a portion of the obverse surface 711 of the heat dissipating member 70. The fifth process P5 is performed such that the protective layer 79 lies outside the sealing resin 50 as viewed in the first direction z. When an external connection component, such as a busbar, is connected to the first connecting surface 131 of the first power terminal 13, the external connection component overlaps with the obverse surface 711 as viewed in the first direction z. Although such connection of an external connection component would normally reduce the dielectric withstand voltage of the semiconductor device A30, this configuration prevents such reduction.

The protective layer 79 contains resin. In the semiconductor device A31, a portion of the protective layer 79 lies between the obverse surface 711 of the heat dissipating member 70 and the sealing resin 50 in the first direction z. This configuration helps reduce delamination of the sealing resin 50 from the obverse surface 711 due to a high affinity between the protective layer 79 and the sealing resin 50.

### Fourth Embodiment

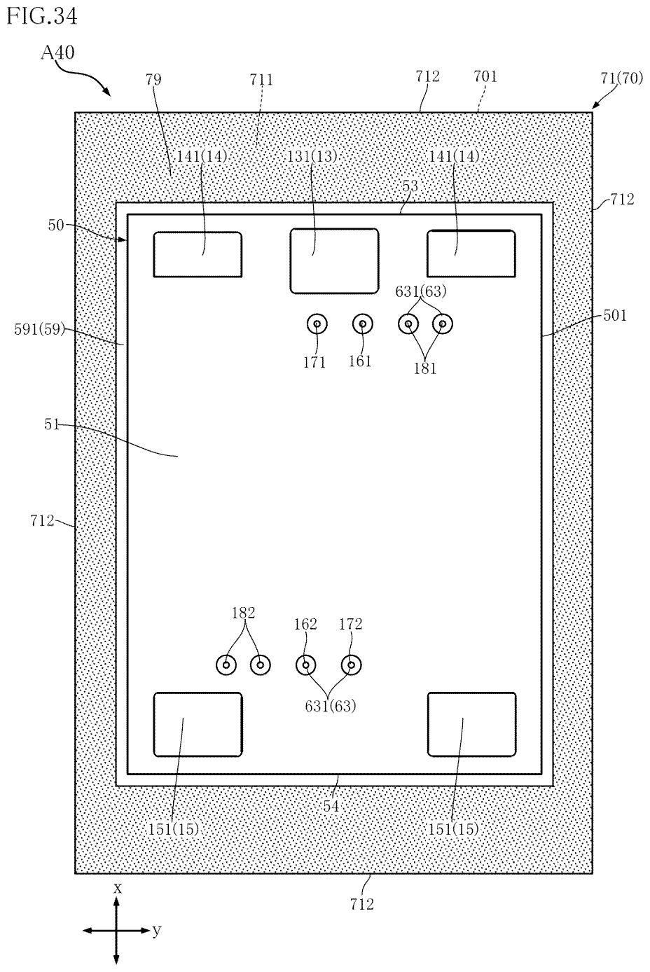

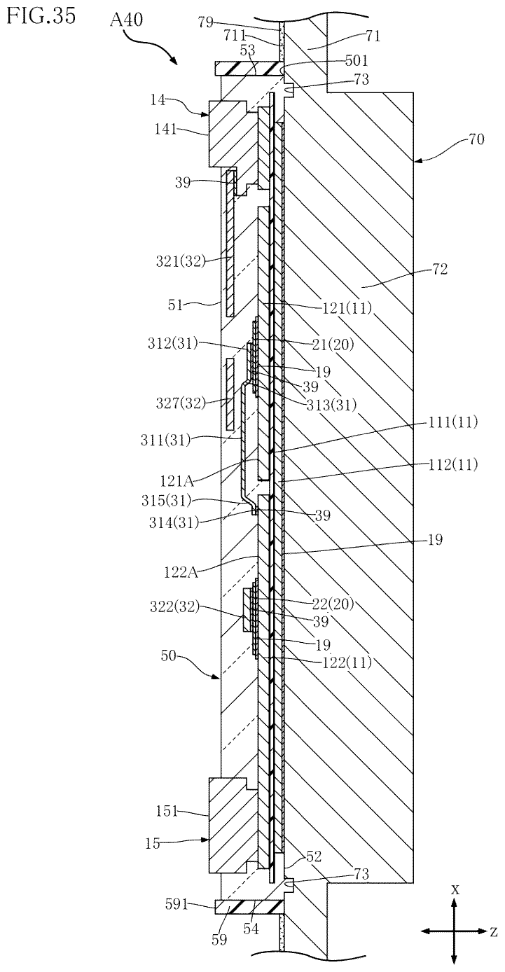

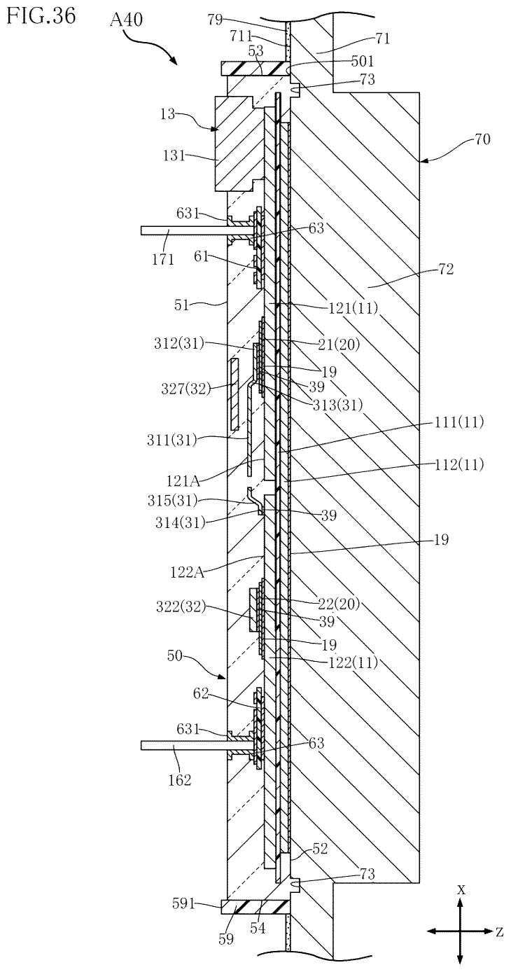

With reference to FIGS. 34 to 36, a semiconductor device A40 according to a fourth embodiment of the present disclosure will be described. In these figures, elements that are identical or similar to those of the semiconductor devices A10 and A30 described above are indicated by the same reference numerals, and redundant descriptions are omitted. FIG. 35 corresponds to FIG. 10, which shows the semiconductor device A10. FIG. 36 corresponds to FIG. 11, which shows the semiconductor device A10.

The semiconductor device A40 differs from the semiconductor device A30 in that it additionally includes a frame structure 59 and has a different configuration for the sealing resin 50.

As shown in FIGS. 34 to 36, the frame structure 59 surrounds the base material 11 as viewed in the first direction z. The frame structure 59 is bonded to the obverse surface 711 of the heat dissipating member 70. The sealing resin 50 is contained in a region enclosed by the frame structure 59. The frame structure 59 is an insulator. The frame structure 59 is made of a material containing at least either resin or a ceramic material. The Young's modulus of the sealing resin 50 is lower than the Young's modulus of the frame structure 59. In this case, the sealing resin 50 is made of a material containing silicone, for example.

As shown in FIGS. 35 and 36, the frame structure 59 has a frame surface 591 that faces the same side as the obverse surface 711 of the heat dissipating member 70 in the first direction z. In the first direction z, the top surface 51 of the sealing resin 50 is positioned between the obverse surface 711 and the frame surface 591. The first power terminal 13, the two second power terminals 14, and the two third power terminals 15 protrude from the top surface 51 of the sealing resin 50. The sealing resin 50 is not formed with the plurality of recesses 55. The first connecting surface 131 of the first power terminal 13, the second connecting surface 141 of each of the two second power terminals 14, and the third connecting surface 151 of each of the two third power terminals 15 are positioned on the side opposite the bottom surface 52 of the sealing resin 50 relative to the top surface 51 in the first direction z.

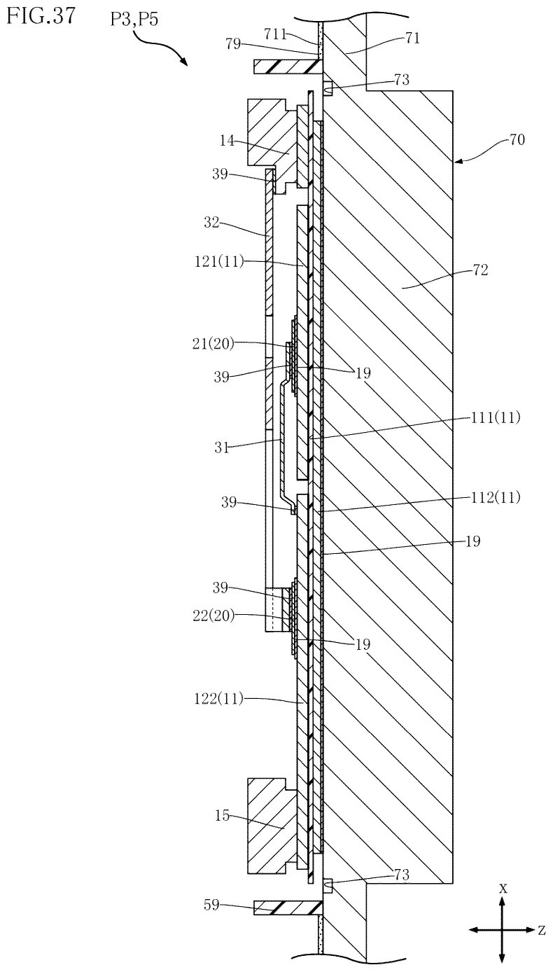

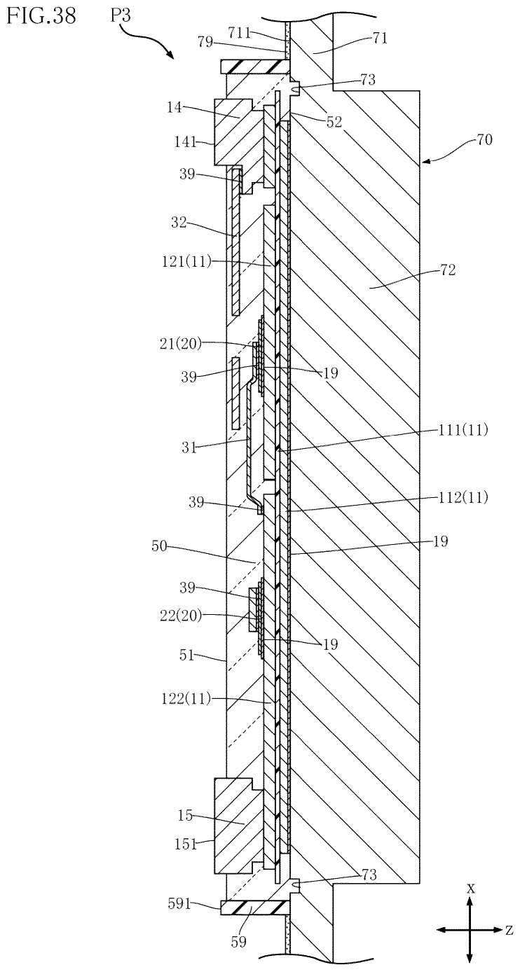

With reference to FIGS. 37 and 38, the following describes an example of a method for manufacturing the semiconductor device A40. FIGS. 37 to 38 correspond to FIG. 35, which shows the semiconductor device A40.

The method for manufacturing the semiconductor device A40 differs from that for the semiconductor device A30 in the third process P3.

As shown in FIG. 37, the third process P3 includes bonding a frame structure 59 that surrounds the base material 11 around the first direction z to the obverse surface 711 of the heat dissipating member 70 before the sealing resin 50 is formed. The fifth process P5 is concurrently performed with the process of bonding the frame structure 59 to the obverse surface 711. Then, the sealing resin 50 is formed as shown in FIG. 38. In the third process P3, the sealing resin 50 is disposed in the region enclosed by the frame structure 59. To form the sealing resin 50, uncured resin is injected into the region using a dispenser. In the third process P3, the sealing resin 50 is formed such that the top surface 51 of the sealing resin 50 is positioned between the obverse surface 711 and the frame surface 591 of the frame structure 59 in the first direction z. Additionally, the first power terminal 13, the two second power terminals 14, and the two third power terminals 15 protrude from the top surface 51.

The following describes effects of the method for manufacturing the semiconductor device A40 and of related aspects.

The method for manufacturing the semiconductor device A40 includes the first process P1, the second process P2, and the third process P3. The first process P1 includes bonding the base material 11, which includes the insulating layer 111, the first conductive layer 121, and the second conductive layer 122, to the heat dissipating member 70. The second process P2 includes bonding each semiconductor element 20 to either the first conductive layer 121 or the second conductive layer 122. The third process P3 includes forming the sealing resin 50 to cover the semiconductor elements 20. In the first process P1, the base material 11 is bonded to the heat dissipating member 70 such that the insulating layer 111 is positioned between the heat dissipating member 70 and each of the first conductive layer 121 and the second conductive layer 122. The third process P3 is performed after completion of each of the first process P1 and the second process P2. Consequently, this method for manufacturing the semiconductor device A40, which includes the base material 11 bonded to the heat dissipating member 70, ensures that the shape of the sealing resin 50 is more reliably retained. Additionally, the method for manufacturing the semiconductor device A40 has a configuration in common with the method for manufacturing the semiconductor device A10, thereby achieving the same effect as the method for manufacturing the semiconductor device A10.

In the method for manufacturing the semiconductor device A40, the third process P3 includes a process of bonding a frame structure 59 that surrounds the base material 11 to the obverse surface 711 of the heat dissipating member 70 before the sealing resin 50 is formed. In the third process P3, the sealing resin 50 is disposed in the region enclosed by the frame structure 59. This configuration allows forming the sealing resin 50 at a temperature lower than that used for transfer molding (about 180° C.).

Fifth Embodiment:

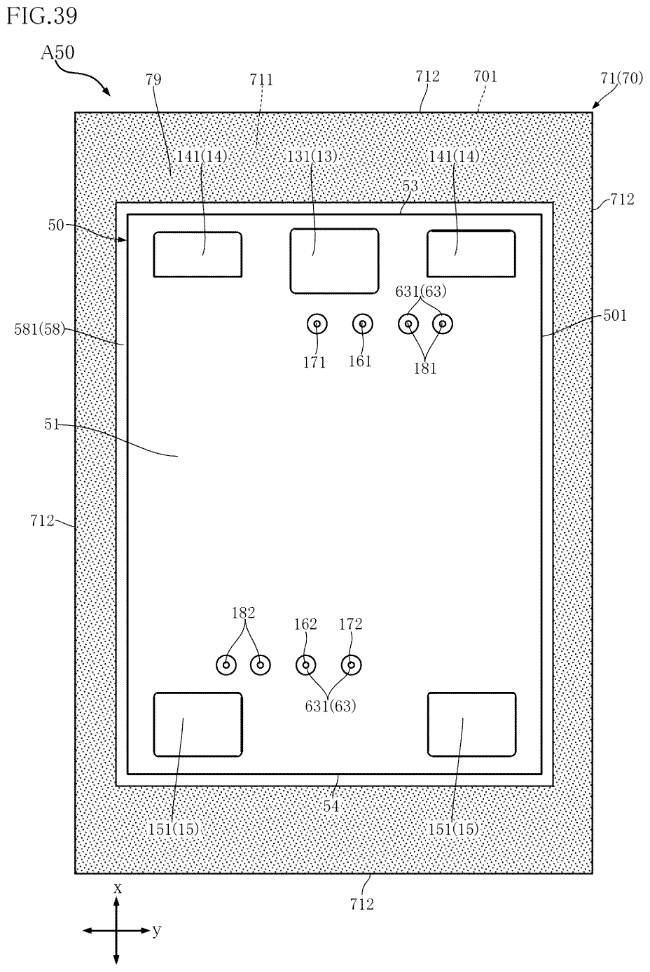

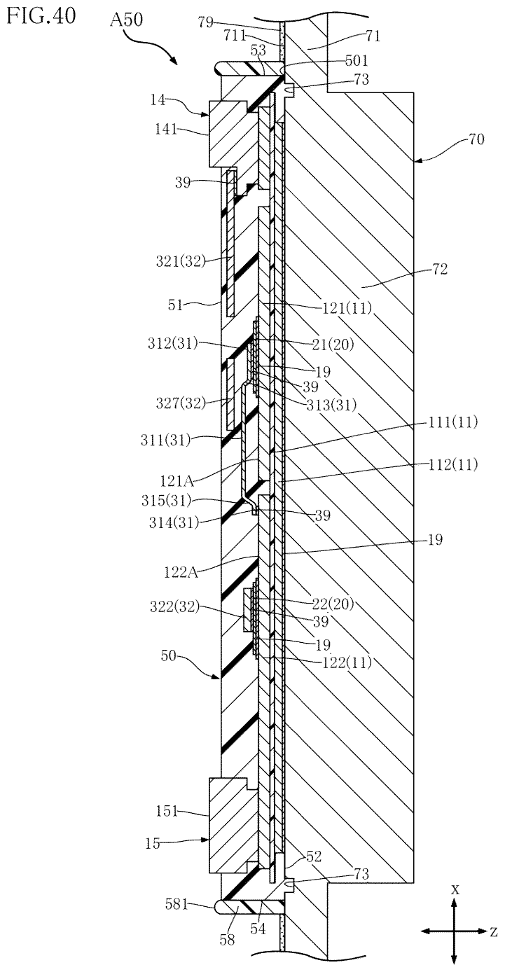

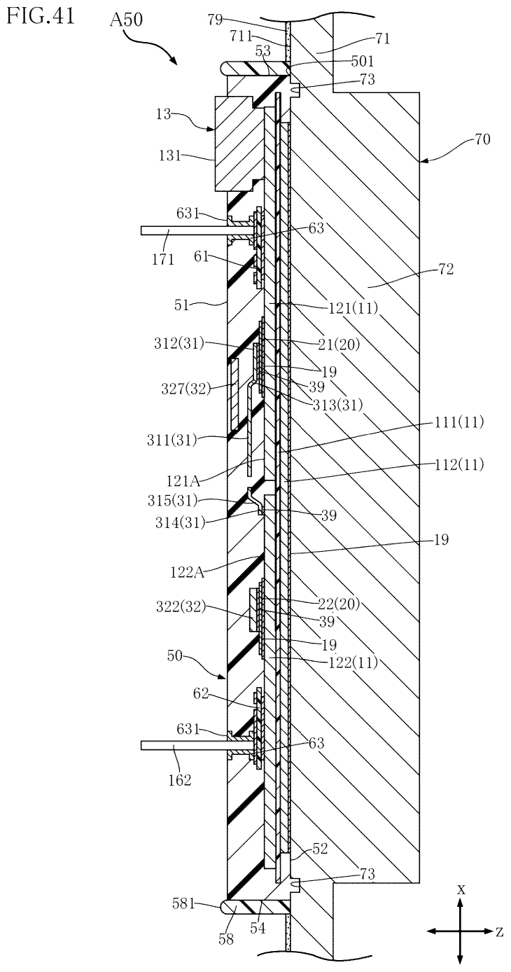

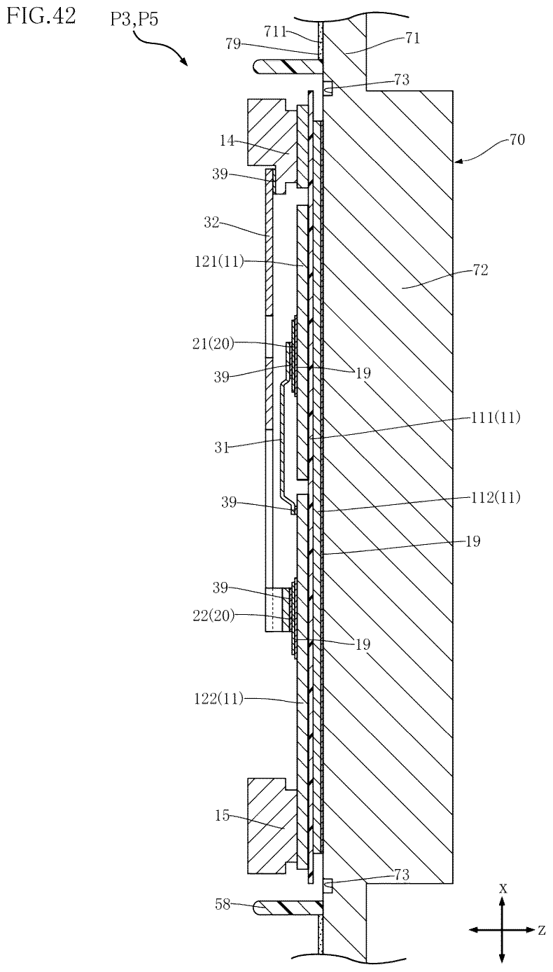

With reference to FIGS. 39 to 41, a semiconductor device A50 according to a fifth embodiment of the present disclosure will be described. In these figures, elements that are identical or similar to those of the semiconductor devices A10 and A30 described above are indicated by the same reference numerals, and redundant descriptions are omitted. FIG. 40 corresponds to FIG. 10, which shows the semiconductor device A10. FIG. 41 corresponds to FIG. 11, which shows the semiconductor device A10.

The semiconductor device A50 differs from the semiconductor device A30 in that it additionally includes a dam structure 58 and has a different configuration for the sealing resin 50.

As shown in FIGS. 39 to 41, the dam structure 58 surrounds the base material 11 as viewed in the first direction z. The dam structure 58 is bonded to the obverse surface 711 of the heat dissipating member 70. The sealing resin 50 is contained in a region enclosed by the dam structure 58. Similarly to the sealing resin 50, the dam structure 58 is made of a material containing resin.

As shown in FIGS. 40 and 41, the dam structure 58 has an end surface 581 that faces the same side as the obverse surface 711 of the heat dissipating member 70 in the first direction z. In the first direction z, the top surface 51 of the sealing resin 50 is positioned between the obverse surface 711 and the end surface 581. The end surface 581 is convex in the first direction z. The first power terminal 13, the two second power terminals 14, and the two third power terminals 15 protrude from the top surface 51 of the sealing resin 50. The sealing resin 50 is not formed with the plurality of recesses 55. The first connecting surface 131 of the first power terminal 13, the second connecting surface 141 of each of the two second power terminals 14, and the third connecting surface 151 of each of the two third power terminals 15 are positioned on the side opposite the bottom surface 52 of the sealing resin 50 relative to the top surface 51 in the first direction z.

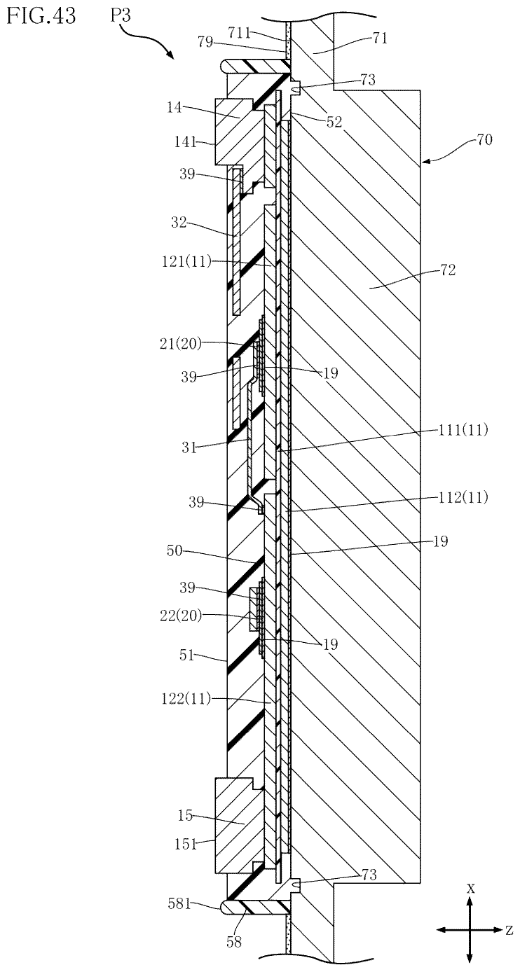

With reference to FIGS. 42 and 43, the following describes an example of a method for manufacturing the semiconductor device A50. FIGS. 42 and 43 correspond to FIG. 40, which shows the semiconductor device A50.

The method for manufacturing the semiconductor device A50 differs from that for the semiconductor device A30 in the third process P3.

As shown in FIG. 42, the third process P3 includes bonding a dam structure 58 that surrounds the base material 11 as viewed in the first direction z to the obverse surface 711 of the heat dissipating member 70 before the sealing resin 50 is formed. The dam structure 58 is formed by applying an uncured resin material to the obverse surface 711, followed by curing. The fifth process P5 is concurrently performed with the process of bonding the dam structure 58. Then, the sealing resin 50 is formed as shown in FIG. 43. In the third process P3, the sealing resin 50 is disposed in the region enclosed by the dam structure 58. To form the sealing resin 50, uncured resin is injected into the region and then cured. The sealing resin 50 before curing has a viscosity different from that of the dam structure 58 before curing. In the third process P3, the sealing resin 50 is formed such that the top surface 51 of the sealing resin 50 is positioned between the obverse surface 711 and the end surface 581 of the dam structure 58 in the first direction z. Additionally, the first power terminal 13, the two second power terminals 14, and the two third power terminals 15 protrude from the top surface 51.

The following describes effects of the method for manufacturing the semiconductor device A50 and of related aspects.

The method for manufacturing the semiconductor device A50 includes the first process P1, the second process P2, and the third process P3. The first process P1 includes bonding the base material 11, which includes the insulating layer 111, the first conductive layer 121, and the second conductive layer 122, to the heat dissipating member 70. The second process P2 includes bonding each semiconductor element 20 to either the first conductive layer 121 or the second conductive layer 122. The third process P3 includes forming the sealing resin 50 to cover the semiconductor elements 20. In the first process P1, the base material 11 is bonded to the heat dissipating member 70 such that the insulating layer 111 is positioned between the heat dissipating member 70 and each of the first conductive layer 121 and the second conductive layer 122. The third process P3 is performed after completion of each of the first process P1 and the second process P2. Consequently, this method for manufacturing the semiconductor device A50, which includes the base material 11 bonded to the heat dissipating member 70, ensures that the shape of the sealing resin 50 is more reliably retained. Additionally, the method for manufacturing the semiconductor device A50 has a configuration in common with the method for manufacturing the semiconductor device A10, thereby achieving the same effect as the method for manufacturing the semiconductor device A10.

The present disclosure is not limited to the foregoing embodiments. Various modifications in design may be made freely in the specific structure of each part of the present disclosure.

The present disclosure includes embodiments described in the following clauses.

Clause 1.

A method for manufacturing a semiconductor device, the method comprising:
a first process of bonding a base material to a heat dissipating member, the base material including an insulating layer and a conductive layer positioned on a first side in a first direction relative to the insulating layer;
a second process of bonding a semiconductor element to the conductive layer; and
a third process of forming a sealing resin that covers the semiconductor element,
wherein in the first process, the base material is bonded to the heat dissipating member with the insulating layer positioned between the heat dissipating member and the conductive layer, and
the third process is performed after completion of each of the first process and the second process.

Clause 2.

The method according to Clause 1, wherein the heat dissipating member includes an obverse surface that faces the base material and an end surface that faces a direction perpendicular to the first direction, and
the third process is performed such that the sealing resin is in contact with the obverse surface, the base material is covered with the sealing resin, and the end surface is exposed from the sealing resin.

Clause 3.

The method according to Clause 2, wherein the third process is performed such that the sealing resin is positioned inside a peripheral edge of the heat dissipating member as viewed in the first direction.

Clause 4.

The method according to Clause 2, wherein in the first process, the base material is bonded to the obverse surface via a first bonding layer, and
a temperature at which the sealing resin is formed in the third process is lower than a temperature at which the first bonding layer is formed in the first process.

Clause 5.

The method according to Clause 4, wherein the base material includes a metal layer positioned on a side opposite the conductive layer relative to the insulating layer, and
in the first process, the metal layer is bonded to the base material.

Clause 6.

The method according to Clause 5, wherein in the first process, pressure is applied to the base material toward the obverse surface in the first direction.

Clause 7.

The method according to any one of Clauses 4 to 6, further comprising a fourth process of electrically bonding a conductive member to the semiconductor element via a second bonding layer,
wherein the fourth process is performed before the third process,
the third process is performed such that the conductive member is covered with the sealing resin, and
the temperature at which the sealing resin is formed in the third process is lower than a temperature at which the second bonding layer is formed in the fourth process.

Clause 8.

The method according to Clause 7, wherein a melting point of the second bonding layer is lower than a melting point of the first bonding layer.

Clause 9.

The method according to Clause 8, further comprising a process of arranging a power terminal electrically connected to the semiconductor element,
wherein the process of arranging the power terminal is performed before the fourth process, and
the third process is performed such that a portion of the power terminal is covered with the sealing resin.

Clause 10.

The method according to Clause 9, wherein in the second process, the semiconductor element is electrically bonded to the conductive layer.

Clause 11.

The method according to Clause 10, wherein the power terminal includes a first power terminal and a second power terminal that are spaced apart from each other,
in the process of arranging the power terminal, the first power terminal is electrically bonded to the conductive layer, and the second power terminal is arranged on the insulating layer, and
in the fourth process, the conductive member is electrically bonded to the second power terminal via the second bonding layer.

Clause 12.

The method according to Clause 11, wherein the second process is concurrently performed with the first process, and
in the second process, the semiconductor element is electrically bonded to the conductive layer via the first bonding layer.

Clause 13.

The method according to Clause 11, wherein the second process is concurrently performed with the fourth process, and
in the second process, the semiconductor element is electrically bonded to the conductive layer via the second bonding layer.

Clause 14.

The method according to Clause 11, wherein the sealing resin includes a top surface that faces the same side as the obverse surface in the first direction, and
the third process is performed such that the power terminal is exposed from the top surface.

Clause 15.

The method according to Clause 14, wherein the heat dissipating member includes an engagement portion that is recessed from the obverse surface, and
the third process is performed such that the sealing resin is received in the engagement portion.
Clause 16.

The method according to Clause 14, further comprising a fifth process of forming a protective layer that covers a portion of the obverse surface and that is an insulator.

Clause 17.

The method according to Clause 16, wherein in the fifth process, the protective layer is formed to lie outside the sealing resin as viewed in the first direction.

Clause 18.

The method according to Clause 5, wherein the first bonding layer is a sintered compact of metal particles containing silver.
Clause 19.

The method according to Clause 6, wherein the first bonding layer is a solid-phase diffusion layer.
Clause 20.

The method according to Clause 8, wherein the second bonding layer contains tin.

Clause 21.

The method according to Clause 14, wherein the third process is performed such that the power terminal protrudes from the top surface.

Clause 22.

The method according to Clause 21, wherein the third process includes bonding a frame structure surrounding the base material to the obverse surface before the forming of the sealing resin, and
the third process is performed such that the sealing resin is disposed in a region enclosed by the frame structure.

Clause 23.

The method according to Clause 22, wherein the frame structure is an insulator.

Clause 24.

The method according to Clause 23, wherein a Young's modulus of the sealing resin is lower than a Young's modulus of the frame structure.

Clause 25.

The method according to Clause 23, wherein the frame structure includes a frame surface that faces the same side as the obverse surface in the first direction, and
in the third process, the sealing resin is formed such that the top surface is positioned between the obverse surface and the frame surface in the first direction.

Clause 26.

The method according to Clause 14, further comprising a process of arranging a signal terminal electrically connected to the semiconductor element,
wherein the process of arranging the signal terminal is performed after the third process, and
the process of arranging the signal terminal is performed such that the signal terminal protrudes from the top surface.

Clause 27.

The method according to Clause 16, wherein the protective layer contains resin.

Clause 28.

A semiconductor device comprising:
a heat dissipating member including an obverse surface that faces a first side in a first direction, and an end surface that faces a direction perpendicular to the first direction;
a base material including a conductive layer and bonded to the obverse surface;
a semiconductor element bonded to the conductive layer; and
a sealing resin covering the base material and the semiconductor element,
wherein the base material includes an insulating layer positioned between the obverse surface and the conductive layer,
the sealing resin is in contact with the obverse surface, and
the end surface is exposed from the sealing resin.

Clause 29.

The semiconductor device according to Clause 28, wherein the sealing resin is positioned inside a peripheral edge of the heat dissipating member as viewed in the first direction.

Clause 30.

The semiconductor device according to Clause 29, further comprising a power terminal that is electrically connected to the semiconductor element,
wherein the sealing resin includes a top surface that faces the same side as the obverse surface in the first direction, and
the power terminal is exposed from the top surface.

Clause 31.

The semiconductor device according to Clause 30, wherein the heat dissipating member includes an engagement portion that is recessed from the obverse surface, and
a portion of the sealing resin is contained in the engagement portion.

Clause 32.

The semiconductor device according to Clause 30 or 31, wherein the base material includes a metal layer positioned between the obverse surface and the insulating layer, and
the metal layer is bonded to the obverse surface.

Clause 33.

The semiconductor device according to Clause 32, wherein each of the conductive layer and the metal layer is positioned inside a peripheral edge of the insulating layer as viewed in the first direction.

Clause 34.

The semiconductor device according to Clause 33, further comprising a conductive member electrically bonded to the semiconductor element,
wherein the semiconductor element is electrically bonded to the conductive layer.

Clause 35.

The semiconductor device according to Clause 34, wherein the power terminal includes a first power terminal electrically bonded to the conductive layer, and a second power terminal disposed above the insulating layer, and
the conductive member is electrically bonded to the second power terminal.

Clause 36.

The semiconductor device according to Clause 35, further comprising a first bonding layer bonding the obverse surface and the metal layer, and a second bonding layer bonding the semiconductor element and the conductive member,
wherein a glass transition point of the sealing resin is lower than a melting point of the first bonding layer and a melting point of the second bonding layer.

Clause 37.

The semiconductor device according to Clause 36, wherein the melting point of the second bonding layer is lower than the melting point of the first bonding layer.

Clause 38.

The semiconductor device according to Clause 37, further comprising a protective layer that covers a portion of the obverse surface and that is an insulator.

Clause 39.

The semiconductor device according to Clause 38, wherein a portion of the protective layer is positioned between the obverse surface and the sealing resin in the first direction.

Clause 40.

The semiconductor device according to Clause 38, further comprising a frame structure that is bonded to the obverse surface and surrounds the base material,
wherein the sealing resin is contained in a region enclosed by the frame structure.

Clause 41.

A vehicle comprising:
a drive source; and
the semiconductor device according to any one of Clauses 28 to 40,
wherein the semiconductor device is electrically connected to the drive source.

1. A method for manufacturing a semiconductor device, the method comprising:
a first process of bonding a base material to a heat dissipating member, the base material including an insulating layer and a conductive layer positioned on a first side in a first direction relative to the insulating layer;
a second process of bonding a semiconductor element to the conductive layer; and
a third process of forming a sealing resin that covers the semiconductor element,
wherein in the first process, the base material is bonded to the heat dissipating member with the insulating layer positioned between the heat dissipating member and the conductive layer, and
the third process is performed after completion of each of the first process and the second process.

2. The method according to claim 1, wherein the heat dissipating member includes an obverse surface that faces the base material and an end surface that faces a direction perpendicular to the first direction, and
the third process is performed such that the sealing resin is in contact with the obverse surface, the base material is covered with the sealing resin, and the end surface is exposed from the sealing resin.

3. The method according to claim 2, wherein the third process is performed such that the sealing resin is positioned inside a peripheral edge of the heat dissipating member as viewed in the first direction.

4. The method according to claim 2, wherein in the first process, the base material is bonded to the obverse surface via a first bonding layer, and
a temperature at which the sealing resin is formed in the third process is lower than a temperature at which the first bonding layer is formed in the first process.

5. The method according to claim 4, wherein the base material includes a metal layer positioned on a side opposite the conductive layer relative to the insulating layer, and
in the first process, the metal layer is bonded to the base material.

6. The method according to claim 5, wherein in the first process, pressure is applied to the base material toward the obverse surface in the first direction.

7. The method according to claim 4, further comprising a fourth process of electrically bonding a conductive member to the semiconductor element via a second bonding layer,
wherein the fourth process is performed before the third process,
the third process is performed such that the conductive member is covered with the sealing resin, and
the temperature at which the sealing resin is formed in the third process is lower than a temperature at which the second bonding layer is formed in the fourth process.

8. The method according to claim 7, wherein a melting point of the second bonding layer is lower than a melting point of the first bonding layer.

9. The method according to claim 8, further comprising a process of arranging a power terminal electrically connected to the semiconductor element,
wherein the process of arranging the power terminal is performed before the fourth process, and
the third process is performed such that a portion of the power terminal is covered with the sealing resin.

10. The method according to claim 9, wherein in the second process, the semiconductor element is electrically bonded to the conductive layer.

11. The method according to claim 10, wherein the power terminal includes a first power terminal and a second power terminal that are spaced apart from each other,
in the process of arranging the power terminal, the first power terminal is electrically bonded to the conductive layer, and the second power terminal is arranged on the insulating layer, and
in the fourth process, the conductive member is electrically bonded to the second power terminal via the second bonding layer.

12. The method according to claim 11, wherein the second process is concurrently performed with the first process, and
in the second process, the semiconductor element is electrically bonded to the conductive layer via the first bonding layer.

13. The method according to claim 11, wherein the second process is concurrently performed with the fourth process, and
in the second process, the semiconductor element is electrically bonded to the conductive layer via the second bonding layer.

14. The method according to claim 11, wherein the sealing resin includes a top surface that faces the same side as the obverse surface in the first direction, and
the third process is performed such that the power terminal is exposed from the top surface.

15. The method according to claim 14, wherein the heat dissipating member includes an engagement portion that is recessed from the obverse surface, and
the third process is performed such that the sealing resin is received in the engagement portion.

16. The method according to claim 14, further comprising a fifth process of forming a protective layer that covers a portion of the obverse surface and that is an insulator.

17. The method according to claim 16, wherein in the fifth process, the protective layer is formed to lie outside the sealing resin as viewed in the first direction.

18. A semiconductor device comprising:
a heat dissipating member including an obverse surface that faces a first side in a first direction, and an end surface that faces a direction perpendicular to the first direction;
a base material including a conductive layer and bonded to the obverse surface;
a semiconductor element bonded to the conductive layer; and
a sealing resin covering the base material and the semiconductor element,
wherein the base material includes an insulating layer positioned between the obverse surface and the conductive layer,
the sealing resin is in contact with the obverse surface, and
the end surface is exposed from the sealing resin.

19. The semiconductor device according to claim 18, wherein the sealing resin lies inside a peripheral edge of the heat dissipating member as viewed in the first direction.

20. A vehicle comprising:
a drive source; and
the semiconductor device according to claim 18,
wherein the semiconductor device is electrically connected to the drive source.
